(19) United States
(12) Patent Application Publication
(10) Pub. No.: US 2025/0310548 A1
(43) Pub. Date: Oct. 2, 2025

(54) METHOD, APPARATUS AND SYSTEM FOR ENCODING AND DECODING A TENSOR

(71) Applicant: CANON KABUSHIKI KAISHA, Tokyo (JP)

(72) Inventors: Christopher James ROSEWARNE, Concord (AU); Thi Hong Nhung NGUYEN, Gladesville (AU)

(21) Appl. No.: 18/881,216

(22) PCT Filed: Jun. 13, 2023
(86) PCT No.: PCT/AU2023/050522

§ 371 Date: Jan. 3, 2025

(30) Foreign Application Priority Data
Jul. 8, 2022 (AU) 2022204911

(51) Int. Cl. H04N 19/33; H04N 19/132; H04N 19/169

(52) U.S. Cl. CPC H04N 19/33; H04N 19/132; H04N 19/169

(57) ABSTRACT

A method for decoding a plurality of tensors forming a hierarchical representation of feature maps for a single frame from a bitstream. The method comprises: decoding a first unit of information from the bitstream; decoding a second unit of information from the bitstream; and determining a first plurality of tensors, feature maps of at least one tensor of the first plurality of tensors having a different spatial resolution from feature maps of other tensor(s). The method also comprises determining a second plurality of tensors, feature maps of at least one tensor of the second plurality of tensors having a different spatial resolution from feature maps of other tensor(s). Feature maps of each tensor of the first plurality of tensors have different spatial resolution from feature maps of each tensor of the second plurality of tensors, and the tensors correspond to the hierarchical representation of feature maps for the single frame.

### REFERENCE TO RELATED APPLICATION(S)

This application claims the benefit under 35 U.S.C. § 119 of the filing date of Australian Patent Application No. 2022204911, filed 8 Jul. 2022, hereby incorporated by reference in its entirety as if fully set forth herein.

### TECHNICAL FIELD

The present invention relates generally to digital video signal processing and, in particular, to a method, apparatus and system for encoding and decoding tensors from a convolutional neural network. The present invention also relates to a computer program product including a computer readable medium having recorded thereon a computer program for encoding and decoding tensors from a convolutional neural network using video compression technology.

### BACKGROUND

Convolution neural networks (CNNs) are an emerging technology addressing, among other things, use cases involving machine vision such as object detection, instance segmentation, object tracking, human pose estimation and action recognition. Applications for CNNs can involve use of ‘edge devices’ with sensors and some processing capability, coupled to application servers as part of a ‘cloud’. CNNs can require relatively high computational complexity, more than can typically be afforded either in computing capacity or power consumption by an edge device. Executing a CNN in a distributed manner has emerged as one solution to running leading edge networks using limited capability edge devices. In other words, distributed processing allows legacy edge devices to still provide the capability of leading edge CNNs by distributing processing between the edge device and external processing means, such as cloud servers.

CNNs typically include many layers, such as convolution layers and fully connected layers, with data passing from one layer to the next in the form of ‘tensors’. Splitting a network across different devices introduces a need to compress the intermediate tensor data that passes from one layer to the next within a CNN, such compression may be referred to as ‘feature compression’, as the intermediate tensor data is often termed ‘features’ of input such as an image frame or video frame. International Organisation for Standardisation/International Electrotechnical Commission Joint Technical Committee 1/Subcommittee 29/Working Groups 2-8 (ISO/IEC JTC1/SC29/WG2-8), also known as the “Moving Picture Experts Group” (MPEG) are tasked with studying compression technology relating to video. WG2 ‘MPEG Technical Requirements’ has established a ‘Video Compression for Machines’ (VCM) ad-hoc group, mandated to study video compression for machine consumption and feature compression. The feature compression mandate is in an exploratory phase with a ‘Call for Evidence’ (CfE) anticipated to be issued, to solicit technology that can significantly outperform feature compression results achieved using state-of-the-art standardised technology.

CNNs require weights for each of the layers to be determined in a training stage, where a very large amount of training data is passed through the CNN and a determined result is compared to ground truth associated with the training data. A process for updating network weights, such as stochastic gradient descent, is applied to iteratively refine the network weights until the network performs at a desired level of accuracy. Where a convolution stage has a ‘stride’ greater than one, an output tensor from the convolution has a lower spatial resolution than a corresponding input tensor. Pooling operations result in an output tensor having smaller dimensions than the input tensor. One example of a pooling operation is ‘max pooling’ (or ‘Maxpool’), which reduces the spatial size of the output tensor compared to the input tensor. Max pooling produces an output tensor by dividing the input tensor into groups of data samples (e.g., a 2×2 group of data samples), and from each group selecting a maximum value as output for a corresponding value in the output tensor. The process of executing a CNN with an input and progressively transforming the input into an output is commonly referred to as ‘inferencing’.

Generally, a tensor has four dimensions, namely: batch, channels, height and width. The first dimension, ‘batch’, of size ‘one’ when inferencing on video data indicates that one frame is passed through a CNN at a time. When training a network, the value of the batch dimension may be increased so that multiple frames are passed through the network before the network weights are updated, according to a predetermined ‘batch size’. A multi-frame video may be passed through as a single tensor with the batch dimension increased in size according to the number of frames of a given video. However, for practical considerations relating to memory consumption and access, inferencing on video data is typically performed on a frame-wise basis. The ‘channels’ dimension indicates the number of concurrent ‘feature maps’ for a given tensor and the height and width dimensions indicate the size of the feature maps at the particular stage of the CNN. Channel count varies through a CNN according to the network architecture. Feature map size also varies, depending on subsampling occurring in specific network layers.

Input to the first layer of a CNN is a batch of one or more images, for example, a single image or video frame, typically resized for compatibility with the dimensionality of the tensor input to the first layer. It is also possible to supply images or video frames in batches of size larger than one. The dimensionality of tensors is dependent on the CNN architecture, generally having some dimensions relating to input width and height and a further ‘channel’ dimension.

Slicing, or reducing a tensor to a collection of two-dimensional arrays, a tensor based on the channel dimension results in a set of two-dimensional ‘feature maps’, so-called because each slice of the tensor has some relationship to the corresponding input image, capturing properties such as various edge types. At layers further from the input to the network, the property can be more abstract. The ‘task performance’ of a CNN is measured by comparing the result of the CNN in performing a task using specific input with a provided ground truth, generally prepared by humans and deemed to indicate a ‘correct’ result.

Once a network topology is decided, the network weights may be updated over time as more training data becomes available. The overall complexity of the CNN tends to be relatively high, with relatively large numbers of multiply-accumulate operations being performed and numerous intermediate tensors being written to and read from memory. In some applications, the CNN is implemented entirely in the ‘cloud’, resulting in a need for high and costly processing power. In other applications, the CNN is implemented in an edge device, such as a camera or mobile phone, resulting in less flexibility but a more distributed processing load. An emerging architecture involves splitting a network into portions, one of the portions run in an edge device and another portion run in the cloud. Such a distributed network architecture may be referred to as ‘collaborative intelligence’ and offers benefits such as re-using a partial result from a first portion of the network with several different second portions, perhaps each portion being optimised for a different task. Collaborative intelligence architectures introduce a need for efficient compression of tensor data, for transmission over a network such as a WAN.

Video compression standards can be used for feature compression, as described below. Various methods can be used to constrict or reduce the data being presented for compression. However, some methods used to constrict or reduce the data being presented for compression can result in a decrease in accuracy unsuitable for some tasks implemented by CNNs.

Feature compression may benefit from existing video compression standards, such as Versatile Video Coding (VVC), developed by the Joint Video Experts Team (JVET). VVC is anticipated to address ongoing demand for ever-higher compression performance, especially as video formats increase in capability (e.g., with higher resolution and higher frame rate) and to address increasing market demand for service delivery over WANs, where bandwidth costs are relatively high. VVC is implementable in contemporary silicon processes and offers an acceptable trade-off between achieved performance versus implementation cost. The implementation cost may be considered for example, in terms of one or more of silicon area, CPU processor load, memory utilisation and bandwidth. Part of the versatility of the VVC standard is in the wide selection of tools available for compressing video data, as well as the wide range of applications for which VVC is suitable. Other video compression standards, such as High Efficiency Video Coding (HEVC) and AV-1, may also be used for feature compression applications.

Video data includes a sequence of frames of image data, each frame including one or more colour channels. Generally, one primary colour channel and two secondary colour channels are needed. The primary colour channel is generally referred to as the ‘luma’ channel and the secondary colour channel(s) are generally referred to as the ‘chroma’ channels. Although video data is typically displayed in an RGB (red-green-blue) colour space, this colour space has a high degree of correlation between the three respective components. The video data representation seen by an encoder or a decoder is often using a colour space such as YCbCr. YCbCr concentrates luminance, mapped to ‘luma’ according to a transfer function, in a Y (primary) channel and chroma in Cb and Cr (secondary) channels. Due to the use of a decorrelated YCbCr signal, the statistics of the luma channel differ markedly from those of the chroma channels. A primary difference is that after quantisation, the chroma channels contain relatively few significant coefficients for a given block compared to the coefficients for a corresponding luma channel block. Moreover, the Cb and Cr channels may be sampled spatially at a lower rate (subsampled) compared to the luma channel, for example half horizontally and half vertically-known as a ‘4:2:0 chroma format’. The 4:2:0 chroma format is commonly used in ‘consumer’ applications, such as internet video streaming, broadcast television, and storage on Blu-Ray™ disks. When only luma samples are present, the resulting monochrome frames are said to use a “4:0:0 chroma format”.

The VVC standard specifies a ‘block based’ architecture, in which frames are firstly divided into a square array of regions known as ‘coding tree units’ (CTUs). CTUs generally occupy a relatively large area, such as 128×128 luma samples. Other possible CTU sizes when using the VVC standard are 32×32 and 64×64. However, CTUs at the right and bottom edge of each frame may be smaller in area, with implicit splitting occurring the ensure the CBs remain in the frame. Associated with each CTU is a ‘coding tree’ either for both the luma channel and the chroma channels (a ‘shared tree’) or a separate tree each for the luma channel and the chroma channels. A coding tree defines a decomposition of the area of the CTU into a set of blocks, also referred to as ‘coding blocks’ (CBs). When a shared tree is in use a single coding tree specifies blocks both for the luma channel and the chroma channels, in which case the collections of collocated coding blocks are referred to as ‘coding units’ (CUs) (i.e., each CU having a coding block for each colour channel). The CBs are processed for encoding or decoding in a particular order. As a consequence of the use of the 4:2:0 chroma format, a CTU with a luma coding tree for a 128×128 luma sample area has a corresponding chroma coding tree for a 64×64 chroma sample area, collocated with the 128×128 luma sample area. When a single coding tree is in use for the luma channel and the chroma channels, the collections of collocated blocks for a given area are generally referred to as ‘units’, for example, the above-mentioned CUs, as well as ‘prediction units’ (PUs), and ‘transform units’ (TUs). A single tree with CUs spanning the colour channels of 4:2:0 chroma format video data result in chroma blocks half the width and height of the corresponding luma blocks. When separate coding trees are used for a given area, the above-mentioned CBs, as well as ‘prediction blocks’ (PBs), and ‘transform blocks’ (TBs) are used.

Notwithstanding the above distinction between ‘units’ and ‘blocks’, the term ‘block’ may be used as a general term for areas or regions of a frame for which operations are applied to all colour channels.

For each CU, a prediction unit (PU) of the contents (sample values) of the corresponding area of frame data is generated (a ‘prediction unit’). Further, a representation of the difference (or ‘spatial domain’ residual) between the prediction and the contents of the area as seen at input to the encoder is formed. The difference in each colour channel may be transformed and coded as a sequence of residual coefficients, forming one or more TUs for a given CU. The applied transform may be a Discrete Cosine Transform (DCT) or other transform, applied to each block of residual values. The transform is applied separably, (i.e., the two-dimensional transform is performed in two passes). The block is firstly transformed by applying a one-dimensional transform to each row of samples in the block. Then, the partial result is transformed by applying a one-dimensional transform to each column of the partial result to produce a final block of transform coefficients that substantially decorrelates the residual samples. Transforms of various sizes are supported by the VVC standard, including transforms of rectangular-shaped blocks, with each side dimension being a power of two. Transform coefficients are quantised for entropy encoding into a bitstream.

VVC features intra-frame prediction and inter-frame prediction. Intra-frame prediction involves the use of previously processed samples in a frame being used to generate a prediction of a current block of data samples in the frame. Inter-frame prediction involves generating a prediction of a current block of samples in a frame using a block of samples obtained from a previously decoded frame. The block of samples obtained from a previously decoded frame is offset from the spatial location of the current block according to a motion vector, which often has filtering applied. Intra-frame prediction blocks can be (i) a uniform sample value (“DC intra prediction”), (ii) a plane having an offset and horizontal and vertical gradient (“planar intra prediction”), (iii) a population of the block with neighbouring samples applied in a particular direction (“angular intra prediction”) or (iv) the result of a matrix multiplication using neighbouring samples and selected matrix coefficients. Further discrepancy between a predicted block and the corresponding input samples may be corrected to an extent by encoding a ‘residual’ into the bitstream. The residual is generally transformed from the spatial domain to the frequency domain to form residual coefficients in a ‘primary transform’ domain. The residual coefficients may be further transformed by application of a ‘secondary transform’ to produce residual coefficients in a ‘secondary transform domain’. Residual coefficients are quantised according to a quantisation parameter, resulting in a loss of accuracy of the reconstruction of the samples produced at the decoder but with a reduction in bitrate in the bitstream. Sequences of pictures may be encoded according to a specified structure of pictures using intra-prediction and pictures using intra- or inter-prediction, and specified dependencies on preceding pictures in coding order, which may differ from display or delivery order. A ‘random access’ configuration results in periodic intra-pictures, forming entry points at which a decoder and commence decoding a bitstream. Other pictures in a random-access configuration generally use inter-prediction to predict content from pictures preceding and following a current picture in display or delivery order, according to a hierarchical structure of specified depth. The use of pictures after a current picture in display order for predicting a current picture requires a degree of picture buffering and delay between the decoding of a given picture and the display (and removal from the buffer) of the given picture.

### SUMMARY

It is an object of the present invention to substantially overcome, or at least ameliorate, one or more disadvantages of existing arrangements.

One aspect of the present disclosure provides a method of decoding at least a plurality of tensors forming a hierarchical representation of feature maps for a single frame from a bitstream, the method comprising: decoding a first unit of information from the bitstream; decoding a second unit of information from the bitstream; determining a first plurality of tensors from the first unit of information, feature maps of at least one tensor of the first plurality of tensors having a different spatial resolution from feature maps of other tensor(s) of the first plurality of tensors; and determining a second plurality of tensors from the second unit of information, feature maps of at least one tensor of the second plurality of tensors having a different spatial resolution from feature maps of other tensor(s) of the second plurality of tensors, wherein feature maps of each tensor of the first plurality of tensors have different spatial resolution from feature maps of each tensor of the second plurality of tensors, and the tensors of the first plurality of tensors and the second plurality of tensors correspond to the hierarchical representation of feature maps for the single frame.

Another aspect of the present disclosure provides a method of encoding at least a plurality of tensors to a bitstream, the plurality of tensors forming a hierarchical representation of feature maps for a single frame, the method comprising: using a convolutional operation to determine a first unit of information from a first plurality of tensors, feature maps of at least one tensor of the first plurality of tensors having a different spatial resolution from feature maps of other tensor(s) of the first plurality of tensors; using a convolutional operation to determine a second unit of information from a second plurality of tensors, feature maps of at least one tensor of the second plurality of tensors having a different spatial resolution from feature maps of other tensor(s) of the second plurality of tensors, and wherein feature maps of each tensor of the first plurality of tensors have different spatial resolution from feature maps of each tensor of the second plurality of tensors, and the tensors of the first plurality of tensors and the second plurality of tensors correspond to the hierarchical representation of feature maps for the single frame; encoding the first unit of information to the bitstream; and encoding the second unit of information to the bitstream.

Another aspect of the present disclosure provides a decoder for decoding at least a plurality of tensors forming a hierarchical representation of feature maps for a single frame from a bitstream, the decoder configured to: decode a first unit of information from the bitstream; decode a second unit of information from the bitstream; determine a first plurality of tensors from the first unit of information, feature maps of at least one tensor of the first plurality of tensors having a different spatial resolution from feature maps of other tensor(s) of the first plurality of tensors; and determine a second plurality of tensors from the second unit of information, feature maps of at least one tensor of the second plurality of tensors having a different spatial resolution from feature maps of other tensor(s) of the second plurality of tensors, wherein feature maps of each tensor of the first plurality of tensors have different spatial resolution from feature maps of each tensor of the second plurality of tensors, and the tensors of the first plurality of tensors and the second plurality of tensors correspond to the hierarchical representation of feature maps for the single frame.

Another aspect of the present disclosure provides an encoder for encoding at least a plurality of tensors to a bitstream, the plurality of tensors forming a hierarchical representation of feature maps for a single frame, the encoder configured to: use a convolutional operation to determine a first unit of information from a first plurality of tensors, feature maps of at least one tensor of the first plurality of tensors having a different spatial resolution from feature maps of other tensor(s) of the first plurality of tensors; use a convolutional operation to determine a second unit of information from a second plurality of tensors, feature maps of at least one tensor of the second plurality of tensors having a different spatial resolution from feature maps of other tensor(s) of the second plurality of tensors, and wherein feature maps of each tensor of the first plurality of tensors have different spatial resolution from feature maps of each tensor of the second plurality of tensors, and the tensors of the first plurality of tensors and the second plurality of tensors correspond to the hierarchical representation of feature maps for the single frame; encode the first unit of information to the bitstream; and encode the second unit of information to the bitstream

Another aspect of the present disclosure provides a non-transitory computer-readable storage medium which stores a program for executing a method of decoding at least a plurality of tensors forming a hierarchical representation of feature maps for a single frame from a bitstream, the method comprising: decoding a first unit of information from the bitstream; decoding a second unit of information from the bitstream; determining a first plurality of tensors from the first unit of information, feature maps of at least one tensor of the first plurality of tensors having a different spatial resolution from feature maps of other tensor(s) of the first plurality of tensors; and determining a second plurality of tensors from the second unit of information, feature maps of at least one tensor of the second plurality of tensors having a different spatial resolution from feature maps of other tensor(s) of the second plurality of tensors, wherein feature maps of each tensor of the first plurality of tensors have different spatial resolution from feature maps of each tensor of the second plurality of tensors, and the tensors of the first plurality of tensors and the second plurality of tensors correspond to the hierarchical representation of feature maps for the single frame.

Another aspect of the present disclosure provides a system comprising: a memory; and a processor, wherein the processor is configured to execute code stored on the memory for implementing a method of decoding at least a plurality of tensors forming a hierarchical representation of feature maps for a single frame from a bitstream, the method comprising: decoding a first unit of information from the bitstream; decoding a second unit of information from the bitstream; determining a first plurality of tensors from the first unit of information, feature maps of at least one tensor of the first plurality of tensors having a different spatial resolution from feature maps of other tensor(s) of the first plurality of tensors; and determining a second plurality of tensors from the second unit of information, feature maps of at least one tensor of the second plurality of tensors having a different spatial resolution from feature maps of other tensor(s) of the second plurality of tensors, wherein feature maps of each tensor of the first plurality of tensors have different spatial resolution from feature maps of each tensor of the second plurality of tensors, and the tensors of the first plurality of tensors and the second plurality of tensors correspond to the hierarchical representation of feature maps for the single frame.

Other aspects are also disclosed.

### BRIEF DESCRIPTION OF THE DRAWINGS

At least one embodiment of the present invention will now be described with reference to the following drawings and an appendix, in which:

FIG. 1 is a schematic block diagram showing a distributed machine task system;

FIGS. 2A and 2B form a schematic block diagram of a general purpose computer system upon which the distributed machine task system of FIG. 1 may be practiced;

FIG. 3A is a schematic block diagram showing functional modules of a backbone portion of a CNN;

FIG. 3B is a schematic block diagram showing a residual block of FIG. 3A;

FIG. 3C is a schematic block diagram showing a residual unit of FIG. 3A;

FIG. 3D is a schematic block diagram showing a CBL module of FIG. 3A;

FIG. 4 is a schematic block diagram showing functional modules of an alternative backbone portion of a CNN;

FIG. 5 is a schematic block diagram showing a cross-layer tensor bottleneck for reducing tensor dimensionality prior to compression;

FIG. 6 shows a method for performing a first portion of a CNN, constricting using a bottleneck encoder, and encoding resulting constricted feature maps;

FIG. 7 is a schematic block diagram showing a packing arrangement for a plurality of compressed tensors;

FIG. 8 is a schematic block diagram showing functional modules of a video encoder;

FIG. 9 is a schematic block diagram showing functional modules of a video decoder;

FIG. 10A is a schematic block diagram showing a cross-layer tensor inverse bottleneck system for restoring tensor dimensionality after compression;

FIG. 10B is a schematic block diagram showing a convolutional arrangement for use with the inverse bottleneck system of FIG. 10A;

FIG. 11 shows a method for decoding a bitstream, reconstructing decorrelated feature maps, and performing a second portion of the CNN

FIG. 12A is a schematic block diagrams showing a head portion of a CNN;

FIG. 12B is a schematic block diagram showing an upscaler module of FIG. 12A;

FIG. 12C is a schematic block diagram showing a detection module of FIG. 12A;

FIG. 13 is a schematic block diagram showing an alternative head portion of a CNN; and

FIG. 14 is a schematic block diagram showing a top-down multi-scale feature reconstruction stage for the destination device.

### DETAILED DESCRIPTION INCLUDING BEST MODE

Where reference is made in any one or more of the accompanying drawings to steps and/or features, which have the same reference numerals, those steps and/or features have for the purposes of this description the same function(s) or operation(s), unless the contrary intention appears.

A distributed machine task system may include an edge device, such as a network camera or smartphone producing intermediate compressed data. The distributed machine task system may also include a final device, such as a server-farm based (‘cloud’) application, operating on the intermediate compressed data to produce some task result. Additionally, the edge device functionality may be embodied in the cloud and the intermediate compressed data may be stored for later processing, potentially for multiple different tasks depending on need. Examples of machine task include object detection and instance segmentation, both of which produce a task result measured as ‘mean average precision’ (mAP) for detection over a threshold value of intersection-over-union (IoU), such as 0.5. Another example machine task is object tracking, with mean object tracking accuracy (MOTA) score as a typical task result.

A convenient form of intermediate compressed data is a compressed video bitstream, owing to the availability of high-performing compression standards and implementations thereof. Video compression standards typically operate on integer samples of some given bit depth, such as 10 bits, arranged in planar arrays. Colour video has three planar arrays, corresponding, for example, to colour components Y, Cb, Cr, or R, G, B, depending on application. CNNs typically operate on floating point data in the form of tensors. Tensors generally have a much smaller spatial dimensionality compared to incoming video data upon which the CNN operates but have many more channels than the three channels typical of colour video data.

Tensors typically have the following dimensions: Frames, channels, height, and width. For example, a tensor of dimensions [1, 256, 76, 136] would be said to contain two-hundred and fifty-six (256) feature maps, each of size 136×76. For video data, inferencing is typically performed one frame at a time, rather than using tensors containing multiple frames.

VVC supports a division of a picture into multiple subpictures, each of which may be independently encoded and independently decoded. In one approach, each subpicture is coded as one ‘slice’, or contiguous sequence of coded CTUs. A ‘tile’ mechanism is also available to divide a picture into a number of independently decodeable regions. Subpictures may be specified in a somewhat flexible manner, with various rectangular sets of CTUs coded as respective subpictures. Flexible definition of subpicture dimensions allows efficiently holding types of data requiring different areas in one picture, avoiding large ‘unused’ areas, i.e., areas of a frame that are not used for reconstruction of tensor data.

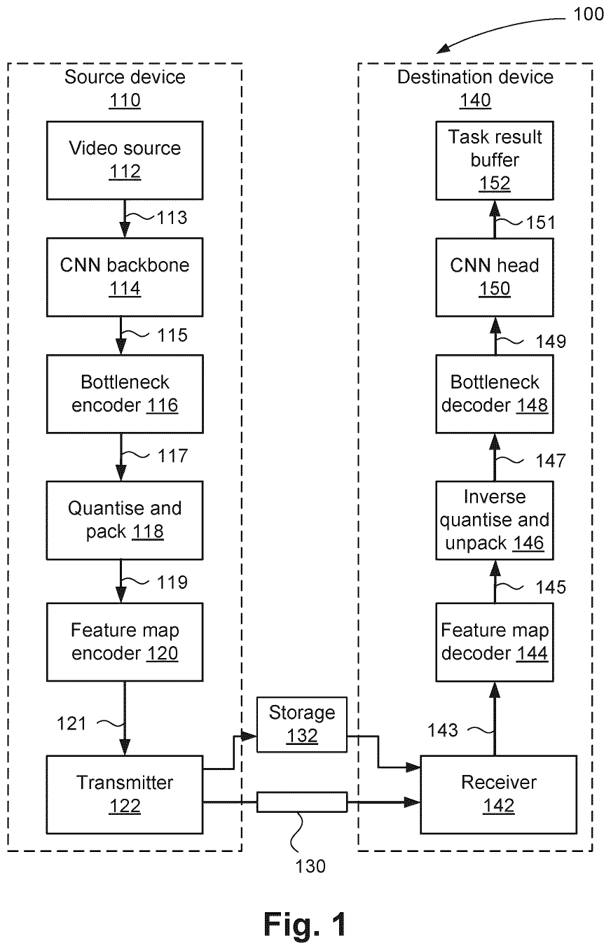

FIG. 1 is a schematic block diagram showing functional modules of a distributed machine task system 100. The notion of distributing a machine task across multiple systems is sometimes referred to as ‘collaborative intelligence’ (CI). The system 100 may be used for implementing methods for decorrelating, packing and quantising feature maps into planar frames for encoding and decoding feature maps from encoded data. The methods may be implemented such that associated overhead data is not too burdensome and task performance on the decoded feature maps is resilient to changing bitrate of the bitstream and the quantised representation of the tensors does not needlessly consume bits where the bits do not provide a commensurate benefit in terms of task performance.

The system 100 includes a source device 110 for generating encoded tensor data 115 from a CNN backbone 114 in the form of encoded video bitstream 121. The system 100 also includes a destination device 140 for decoding tensor data in the form of an encoded video bitstream 143. A communication channel 130 is used to communicate the encoded video bitstream 121 from the source device 110 to the destination device 140. In some arrangements, the source device 110 and destination device 140 may either or both comprise respective mobile telephone handsets (e.g., “smartphones”) or network cameras and cloud applications. The communication channel 130 may be a wired connection, such as Ethernet, or a wireless connection, such as WiFi or 5G, including connections across a Wide Area Network (WAN) or across ad-hoc connections. Moreover, the source device 110 and the destination device 140 may comprise applications where encoded video data is captured on some computer-readable storage medium, such as a hard disk drive in a file server or memory.

As shown in FIG. 1, the source device 110 includes a video source 112, the CNN backbone 114, a bottleneck encoder 116, a quantise and pack module 118, a feature map encoder 120, and a transmitter 122. The video source 112 typically comprises a source of captured video frame data (shown as 113), such as an image capture sensor, a previously captured video sequence stored on a non-transitory recording medium, or a video feed from a remote image capture sensor. The video source 112 may also be an output of a computer graphics card, for example, displaying the video output of an operating system and various applications executing upon a computing device (e.g., a tablet computer). Examples of source devices 110 that may include an image capture sensor as the video source 112 include smart-phones, video camcorders, professional video cameras, and network video cameras. The system 100 reduces dimensionality of tensors at the interface between the first network portion and the second network portion using a ‘bottleneck’, i.e., additional network layers that restrict tensor dimensionality on the encoding side and restore tensor dimensionality at the decoder side. The multi-scale representation produced by a feature pyramid network (FPN) is ‘fused’ together into a single tensor using an approach named ‘multi-scale feature compression’ (MSFC). MSFC is ordinarily used to merge all FPN layers into a single tensor. Merging all FPN layers into a single tensor is implemented at the expense of spatial detail for the less decomposed (larger) layers of the FPN. The loss of spatial detail can result in an unacceptable decrease in accuracy for some tasks or operations implemented by the system 100.

The arrangements described separate tensors of the FPN into groups and separately apply MSFC techniques rather than merging all FPN layers into a single tensor. Separately applying MFSC techniques permits a degree of cross-layer fusion without such severe degradation of spatial detail. For tasks requiring preservation of greater spatial detail, such as instance segmentation, the resulting mAP is higher using separate MSFC techniques than if all FPN layers are merged into a single tensor with low spatial resolution.

The CNN backbone 114 receives the video frame data 113 and performs specific layers of an overall CNN, such as layers corresponding to the ‘backbone’ of the CNN, outputting tensors 115. The backbone layers of the CNN may produce multiple tensors as output, for example, corresponding to different spatial scales of an input image represented by the video frame data 113, sometimes referred to as a ‘feature pyramid network’ (FPN) architecture. The tensors resulting from an FPN backbone form a hierarchical representation of the frame data 113 including data of feature maps. Each successive layer of the hierarchical representation has half the width and height of the preceding layer. Later layers that are produced further into in the backbone network tend to contain feature having a more abstract representation of the frame data 113. Less decomposed layers, produced earlier in the backbone network, tend to contain features representing less abstract features of the frame data 113, such as various geometric properties such as edges of various angles. An FPN may result in three tensors, corresponding to three layers, output from the backbone 114 as the tensors 115 when a ‘YOLOv3’ network is performed by the system 100, with varying spatial resolution and channel count. When the system 100 is performing networks such as ‘Faster RCNN X101-FPN” or “Mask RCNN X101-FPN” the tensors 115 include tensors for four layers P2-P5. The bottleneck encoder 116 receives tensors 115. The bottleneck encoder 116 acts to compress one or more internal layers of the overall CNN. The internal layers of the overall CNN provide the output of the CNN backbone 114, compressed or constricted by the bottleneck encoder 116 using a set of neural network layers trained to convert to a lower channel count and smaller spatial resolution than required by the tensors 115. The bottleneck encoder 116 outputs bottleneck tensors 117. The bottleneck tensors 117 are passed to the quantise and pack module 118. Each feature map of the bottleneck tensors 117 is quantised from floating point to integer precision and packed into a monochrome frame by the module 118 to produce the frame 119. The frame 119 is encoded by the feature map encoder 120 to produce a bitstream 121. The bitstream 121 is supplied to the transmitter 122 for transmission over the communications channel 130 or the bitstream 121 is written to storage 132 for later use.

The source device 110 supports a particular network for the CNN backbone 114. However, the destination device 140 may use one of several networks for the head CNN 150. In this way, partially processed data in the form of packed feature maps may be stored for later use in performing various tasks without needing to repeatedly perform the operation of the CNN backbone 114.

The bitstream 121 is transmitted by the transmitter 122 over the communication channel 130 as encoded video data (or “encoded video information”). The bitstream 121 can in some implementations be stored in the storage 132, where the storage 132 is a non-transitory storage device such as a “Flash” memory or a hard disk drive, until later being transmitted over the communication channel 130 (or in-lieu of transmission over the communication channel 130). For example, encoded video data may be served upon demand to customers over a wide area network (WAN) for a video analytics application.

The destination device 140 includes a receiver 142, a feature map decoder 144, an unpack and inverse quantise module 146, a bottle neck decoder 148, a CNN head 150, and a CNN task result buffer 152. The receiver 142 receives encoded video data from the communication channel 130 and passes the video bitstream 143 to the feature map decoder 144. The feature map decoder 144 operates to decode the feature maps and output a decoded frame 145. The decoded frame 145 is passed to the unpack and inverse quantise module 146. The module 146 unpacks and inverse quantises the tensors of the frame 145 to generate dequantized tensors, output as decoded bottleneck tensors 147. The decoded bottleneck tensors 147 are supplied to the bottleneck decoder 148. The bottleneck decoder 148 performs the inverse operation of the bottleneck encoder 116, to produce extracted tensors 149. The extracted tensors 149 are passed to the CNN head 150. The CNN head 150 performs the later layers of the task that began with the CNN backbone 114 to produce a task result 151, which is stored in a task result buffer 152. The contents of the task result buffer 152 may be presented to the user, e.g., via a graphical user interface, or provided to an analytics application where some action is decided based on the task result, which may include summary level presentation of aggregated task results to a user. It is also possible for the functionality of each of the source device 110 and the destination device 140 to be embodied in a single device, examples of which include mobile telephone handsets and tablet computers and cloud applications.

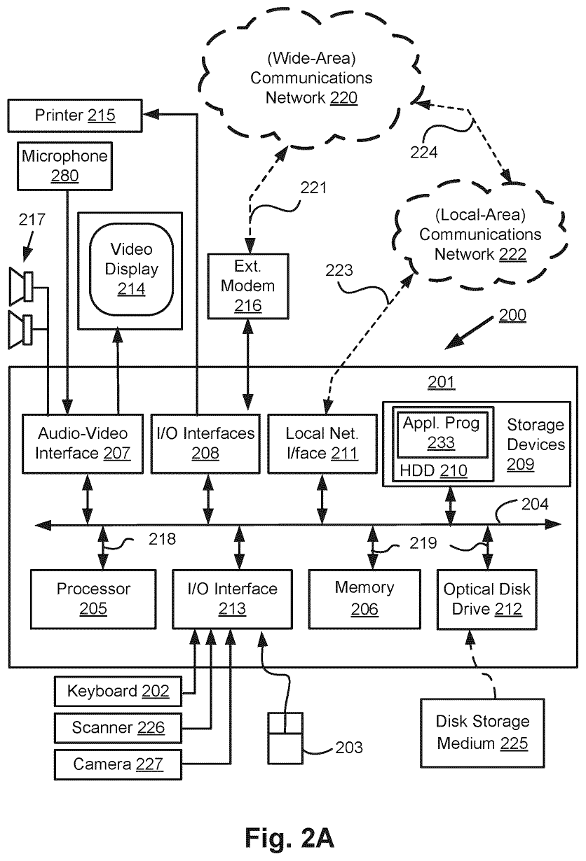

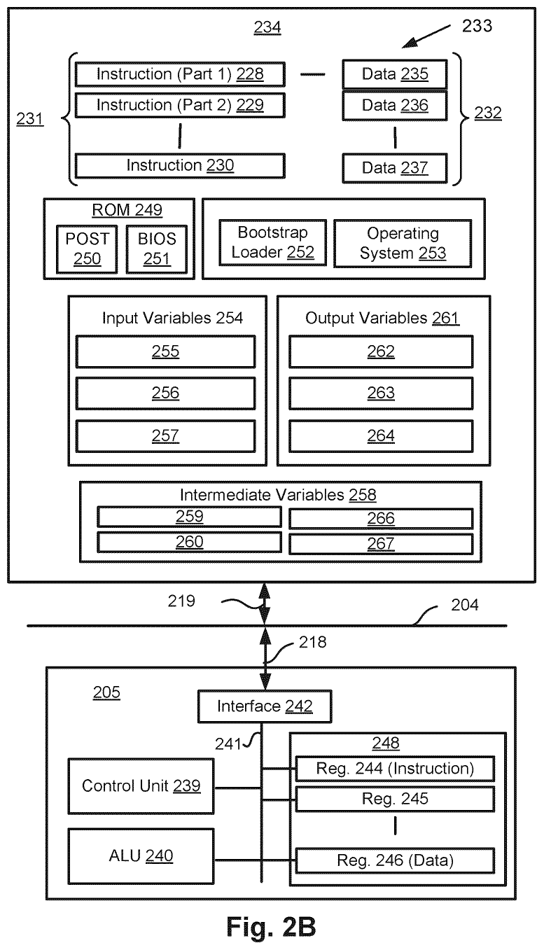

Notwithstanding the example devices mentioned above, each of the source device 110 and destination device 140 may be configured within a general-purpose computing system, typically through a combination of hardware and software components. FIG. 2A illustrates such a computer system 200, which includes: a computer module 201; input devices such as a keyboard 202, a mouse pointer device 203, a scanner 226, a camera 227, which may be configured as the video source 112, and a microphone 280; and output devices including a printer 215, a display device 214, which may be configured as a display device presenting the task result 151, and loudspeakers 217. An external Modulator-Demodulator (Modem) transceiver device 216 may be used by the computer module 201 for communicating to and from a communications network 220 via a connection 221. The communications network 220, which may represent the communication channel 130, may be a (WAN), such as the Internet, a cellular telecommunications network, or a private WAN. Where the connection 221 is a telephone line, the modem 216 may be a traditional “dial-up” modem. Alternatively, where the connection 221 is a high capacity (e.g., cable or optical) connection, the modem 216 may be a broadband modem. A wireless modem may also be used for wireless connection to the communications network 220. The transceiver device 216 may provide the functionality of the transmitter 122 and the receiver 142 and the communication channel 130 may be embodied in the connection 221.

The computer module 201 typically includes at least one processor unit 205, and a memory unit 206. For example, the memory unit 206 may have semiconductor random access memory (RAM) and semiconductor read only memory (ROM). The computer module 201 also includes a number of input/output (I/O) interfaces including: an audio-video interface 207 that couples to the video display 214, loudspeakers 217 and microphone 280; an I/O interface 213 that couples to the keyboard 202, mouse 203, scanner 226, camera 227 and optionally a joystick or other human interface device (not illustrated); and an interface 208 for the external modem 216 and printer 215. The signal from the audio-video interface 207 to the computer monitor 214 is generally the output of a computer graphics card. In some implementations, the modem 216 may be incorporated within the computer module 201, for example within the interface 208. The computer module 201 also has a local network interface 211, which permits coupling of the computer system 200 via a connection 223 to a local-area communications network 222, known as a Local Area Network (LAN). As illustrated in FIG. 2A, the local communications network 222 may also couple to the wide network 220 via a connection 224, which would typically include a so-called “firewall” device or device of similar functionality. The local network interface 211 may comprise an Ethernet™ circuit card, a Bluetooth™ wireless arrangement or an IEEE 802.11 wireless arrangement; however, numerous other types of interfaces may be practiced for the interface 211. The local network interface 211 may also provide the functionality of the transmitter 122 and the receiver 142 and communication channel 130 may also be embodied in the local communications network 222.

The I/O interfaces 208 and 213 may afford either or both of serial and parallel connectivity, the former typically being implemented according to the Universal Serial Bus (USB) standards and having corresponding USB connectors (not illustrated). Storage devices 209 are provided and typically include a hard disk drive (HDD) 210. Other storage devices such as a floppy disk drive and a magnetic tape drive (not illustrated) may also be used. An optical disk drive 212 is typically provided to act as a non-volatile source of data. Portable memory devices, such optical disks (e.g., CD-ROM, DVD, Blu ray Disc™), USB-RAM, portable, external hard drives, and floppy disks, for example, may be used as appropriate sources of data to the computer system 200. Typically, any of the HDD 210, optical drive 212, networks 220 and 222 may also be configured to operate as the video source 112, or as a destination for decoded video data to be stored for reproduction via the display 214. The source device 110 and the destination device 140 of the system 100 may be embodied in the computer system 200.

The components 205 to 213 of the computer module 201 typically communicate via an interconnected bus 204 and in a manner that results in a conventional mode of operation of the computer system 200 known to those in the relevant art. For example, the processor 205 is coupled to the system bus 204 using a connection 218. Likewise, the memory 206 and optical disk drive 212 are coupled to the system bus 204 by connections 219. Examples of computers on which the described arrangements can be practised include IBM-PC's and compatibles, Sun SPARCstations, Apple Mac™ or alike computer systems.

Where appropriate or desired, the source device 110 and the destination device 140, as well as methods described below, may be implemented using the computer system 200. In particular, the source device 110, the destination device 140 and methods to be described, may be implemented as one or more software application programs 233 executable within the computer system 200. The source device 110, the destination device 140 and the steps of the described methods are effected by instructions 231 (see FIG. 2B) in the software 233 that are carried out within the computer system 200. The software instructions 231 may be formed as one or more code modules, each for performing one or more particular tasks. The software may also be divided into two separate parts, in which a first part and the corresponding code modules performs the described methods and a second part and the corresponding code modules manage a user interface between the first part and the user.

The software may be stored in a computer readable medium, including the storage devices described below, for example. The software is loaded into the computer system 200 from the computer readable medium, and then executed by the computer system 200. A computer readable medium having such software or computer program recorded on the computer readable medium is a computer program product. The use of the computer program product in the computer system 200 preferably effects an advantageous apparatus for implementing the source device 110 and the destination device 140 and the described methods.

The software 233 is typically stored in the HDD 210 or the memory 206. The software is loaded into the computer system 200 from a computer readable medium and executed by the computer system 200. Thus, for example, the software 233 may be stored on an optically readable disk storage medium (e.g., CD-ROM) 225 that is read by the optical disk drive 212.

In some instances, the application programs 233 may be supplied to the user encoded on one or more CD-ROMs 225 and read via the corresponding drive 212, or alternatively may be read by the user from the networks 220 or 222. Still further, the software can also be loaded into the computer system 200 from other computer readable media. Computer readable storage media refers to any non-transitory tangible storage medium that provides recorded instructions and/or data to the computer system 200 for execution and/or processing. Examples of such storage media include floppy disks, magnetic tape, CD-ROM, DVD, Blu-ray Disc™, a hard disk drive, a ROM or integrated circuit, USB memory, a magneto-optical disk, or a computer readable card such as a PCMCIA card and the like, whether or not such devices are internal or external of the computer module 201. Examples of transitory or non-tangible computer readable transmission media that may also participate in the provision of the software, application programs, instructions and/or video data or encoded video data to the computer module 201 include radio or infra-red transmission channels, as well as a network connection to another computer or networked device, and the Internet or Intranets including e-mail transmissions and information recorded on Websites and the like.

The second part of the application program 233 and the corresponding code modules mentioned above may be executed to implement one or more graphical user interfaces (GUIs) to be rendered or otherwise represented upon the display 214. Through manipulation of typically the keyboard 202 and the mouse 203, a user of the computer system 200 and the application may manipulate the interface in a functionally adaptable manner to provide controlling commands and/or input to the applications associated with the GUI(s). Other forms of functionally adaptable user interfaces may also be implemented, such as an audio interface utilizing speech prompts output via the loudspeakers 217 and user voice commands input via the microphone 280.

FIG. 2B is a detailed schematic block diagram of the processor 205 and a “memory” 234. The memory 234 represents a logical aggregation of all the memory modules (including the storage devices 209 and semiconductor memory 206) that can be accessed by the computer module 201 in FIG. 2A.

When the computer module 201 is initially powered up, a power-on self-test (POST) program 250 executes. The POST program 250 is typically stored in a ROM 249 of the semiconductor memory 206 of FIG. 2A. A hardware device such as the ROM 249 storing software is sometimes referred to as firmware. The POST program 250 examines hardware within the computer module 201 to ensure proper functioning and typically checks the processor 205, the memory 234 (209, 206), and a basic input-output systems software (BIOS) module 251, also typically stored in the ROM 249, for correct operation. Once the POST program 250 has run successfully, the BIOS 251 activates the hard disk drive 210 of FIG. 2A. Activation of the hard disk drive 210 causes a bootstrap loader program 252 that is resident on the hard disk drive 210 to execute via the processor 205. This loads an operating system 253 into the RAM memory 206, upon which the operating system 253 commences operation. The operating system 253 is a system level application, executable by the processor 205, to fulfil various high-level functions, including processor management, memory management, device management, storage management, software application interface, and generic user interface.

The operating system 253 manages the memory 234 (209, 206) to ensure that each process or application running on the computer module 201 has sufficient memory in which to execute without colliding with memory allocated to another process. Furthermore, the different types of memory available in the computer system 200 of FIG. 2A need to be used properly so that each process can run effectively. Accordingly, the aggregated memory 234 is not intended to illustrate how particular segments of memory are allocated (unless otherwise stated), but rather to provide a general view of the memory accessible by the computer system 200 and how such memory is used.

As shown in FIG. 2B, the processor 205 includes a number of functional modules including a control unit 239, an arithmetic logic unit (ALU) 240, and a local or internal memory 248, sometimes called a cache memory. The cache memory 248 typically includes a number of storage registers 244-246 in a register section. One or more internal busses 241 functionally interconnect these functional modules. The processor 205 typically also has one or more interfaces 242 for communicating with external devices via the system bus 204, using a connection 218. The memory 234 is coupled to the bus 204 using a connection 219.

The application program 233 includes a sequence of instructions 231 that may include conditional branch and loop instructions. The program 233 may also include data 232 which is used in execution of the program 233. The instructions 231 and the data 232 are stored in memory locations 228, 229, 230 and 235, 236, 237, respectively. Depending upon the relative size of the instructions 231 and the memory locations 228-230, a particular instruction may be stored in a single memory location as depicted by the instruction shown in the memory location 230. Alternately, an instruction may be segmented into a number of parts each of which is stored in a separate memory location, as depicted by the instruction segments shown in the memory locations 228 and 229.

In general, the processor 205 is given a set of instructions which are executed therein. The processor 205 waits for a subsequent input, to which the processor 205 reacts to by executing another set of instructions. Each input may be provided from one or more of a number of sources, including data generated by one or more of the input devices 202, 203, data received from an external source across one of the networks 220, 202, data retrieved from one of the storage devices 206, 209 or data retrieved from a storage medium 225 inserted into the corresponding reader 212, all depicted in FIG. 2A. The execution of a set of the instructions may in some cases result in output of data. Execution may also involve storing data or variables to the memory 234.

The bottleneck encoder 116, the bottleneck decoder 148 and the described methods may use input variables 254, which are stored in the memory 234 in corresponding memory locations 255, 256, 257. The bottleneck encoder 116, the bottleneck decoder 148 and the described methods produce output variables 261, which are stored in the memory 234 in corresponding memory locations 262, 263, 264. Intermediate variables 258 may be stored in memory locations 259, 260, 266 and 267.

Referring to the processor 205 of FIG. 2B, the registers 244, 245, 246, the arithmetic logic unit (ALU) 240, and the control unit 239 work together to perform sequences of micro-operations needed to perform “fetch, decode, and execute” cycles for every instruction in the instruction set making up the program 233. Each fetch, decode, and execute cycle comprises:
a fetch operation, which fetches or reads an instruction 231 from a memory location 228, 229, 230;
a decode operation in which the control unit 239 determines which instruction has been fetched; and
an execute operation in which the control unit 239 and/or the ALU 240 execute the instruction.

Thereafter, a further fetch, decode, and execute cycle for the next instruction may be executed. Similarly, a store cycle may be performed by which the control unit 239 stores or writes a value to a memory location 232.

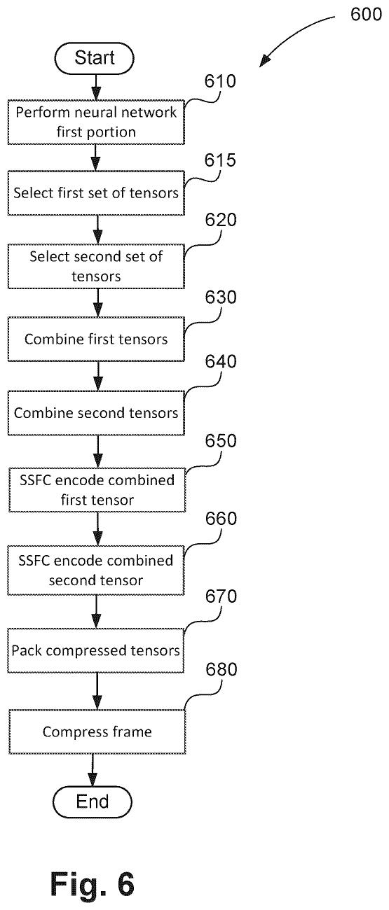

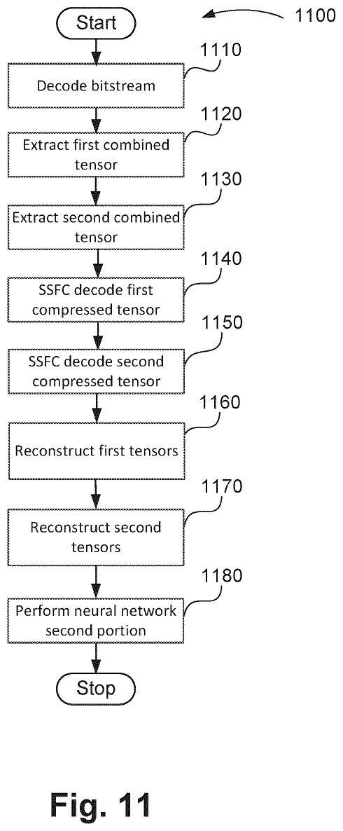

Each step or sub-process in the methods of FIGS. 6 and 11, to be described, is associated with one or more segments of the program 233 and is typically performed by the register section 244, 245, 247, the ALU 240, and the control unit 239 in the processor 205 working together to perform the fetch, decode, and execute cycles for every instruction in the instruction set for the noted segments of the program 233.

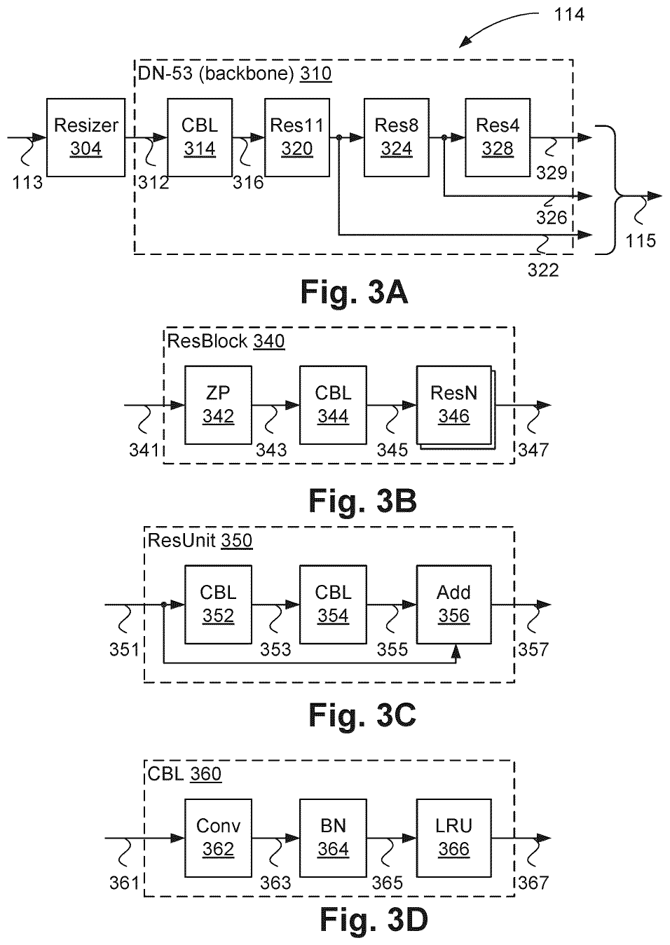

FIG. 3A is a schematic block diagram showing functional modules of a backbone portion 310 of a CNN, which may serve as the CNN backbone 114. The backbone portion 114 is sometimes referred to as ‘DarkNet-53’ and forms the backbone of a ‘YOLOv3’ object detection network. Different backbones are also possible, resulting in a different number of and dimensionality of layers of the tensors 115 for each frame.

As shown in FIG. 3A, the video data 113 is passed to a resizer module 304. The resizer module 314 resizes the frame to a resolution suitable for processing by the CNN backbone 310, producing resized frame data 312. If the resolution of the frame data 113 is already suitable for the CNN backbone 310 then operation of the resizer module 304 is not needed. The resized frame data 312 is passed to a convolutional batch normalisation leaky rectified linear (CBL) module 314 to produce tensors 316. The CBL 314 contains modules as described with reference to a CBL module 360, as shown in FIG. 3D.

Referring to FIG. 3D, the CBL module 360 takes as input a tensor 361. The tensor 361 is passed to a convolutional layer 362 to produce tensor 363. When the convolutional layer 362 has a stride of one and padding is set to k samples, with a convolutional kernel of size 2k+1, the tensor 363 has the same spatial dimensions as the tensor 361. When the convolution layer 362 has a larger stride, such as two, the tensor 363 has smaller spatial dimensions compared to the tensor 361, for example, halved in size for the stride of two. Regardless of the stride, the size of channel dimension of the tensor 363 may vary compared to the channel dimension of the tensor 361 for a particular CBL block. The tensor 363 is passed to a batch normalisation module 364 which outputs a tensor 365. The batch normalisation module 364 normalizes the input tensor 363, applies a scaling factor and offset value to produce the output tensor 365. The scaling factor and offset value are derived from a training process. The tensor 365 is passed to a leaky rectified linear activation (“LeakyReLU”) module 366 to produce a tensor 367. The module 366 provides a ‘leaky’ activation function whereby positive values in the tensor are passed through and negative values are severely reduced in magnitude, for example, to 0.1× their former value.

Returning to FIG. 3A, the tensor 316 is passed from the CBL block 314 to a residual block 11 module 320. The module 320 contains a sequential concatenation of three residual blocks, containing 1, 2, and 8 residual units internally, respectively.

A residual block, such as present in the module 320, is described with reference to a ResBlock 340 as shown in FIG. 3B. The ResBlock 340 receives a tensor 341. The tensor is zero-padded by a zero-padding module 342 to produce a tensor 343. The tensor 343 is passed to a CBL module 344 to produce a tensor 345. The tensor 345 is passed to a residual unit 346, of which the residual block 340 includes a series of concatenated residual units. The last residual unit of the residual units 346 outputs a tensor 347.

A residual unit, such as the unit 346, is described with reference to a ResUnit 350 as shown in FIG. 3C. The ResUnit 350 takes a tensor 351 as input. The tensor 351 is passed to a CBL module 352 to produce a tensor 353. The tensor 353 is passed to a second CBL unit 354 to produce a tensor 355. An add module 356 sums the tensor 355 with the tensor 351 to produce a tensor 357. The add module 356 may also be referred to as a ‘shortcut’ as the input tensor 351 substantially influences the output tensor 357. For an untrained network, ResUnit 350 acts to pass-through tensors. As training is performed, the CBL modules 352 and 354 act to deviate the tensor 357 away from the tensor 351 in accordance with training data and ground truth data.

The Res11 module 320 outputs a tensor 322. The tensor 322 is output from the backbone module 310 as one of the layers and also provided to a Res8 module 324. The Res8 module 324 is a residual block (i.e., 340), which includes eight residual units (i.e. 350). The Res8 module 324 produces a tensor 326. The tensor 326 is passed to a Res4 module 328 and output from the backbone module 310 as one of the layers. The Res4 module is a residual block (i.e., 340), which includes four residual units (i.e., 350). The Res4 module 324 produces a tensor 329. The tensor 329 is output from the backbone module 310 as one of the layers. Collectively, the layer tensors 322, 326, and 329 are output as tensors 115. The backbone CNN 310 may take as input a video frame of resolution 1088×608 and produce three tensors, corresponding to three layers, with the following dimensions: [1, 256, 76, 136], [1, 512, 38, 68], [1, 1024, 19, 34]. Another example of the three tensors corresponding to three layers may be [1, 512, 34, 19], [1, 256, 68, 38], [1, 128, 136, 76] which are respectively separated at 75th network layer, 90th network layer, and 105th network layer in the CNN 310. Each tensor can have a different resolution to the next tensor. The resolution of each tensors can double in height and width between respective tensors. In forming the output tenors 115, the 322, 326, and 329 provide a hierarchical representation of the frame data including data of feature maps for encoding to the bitstream. The separating points depend on the CNN310.

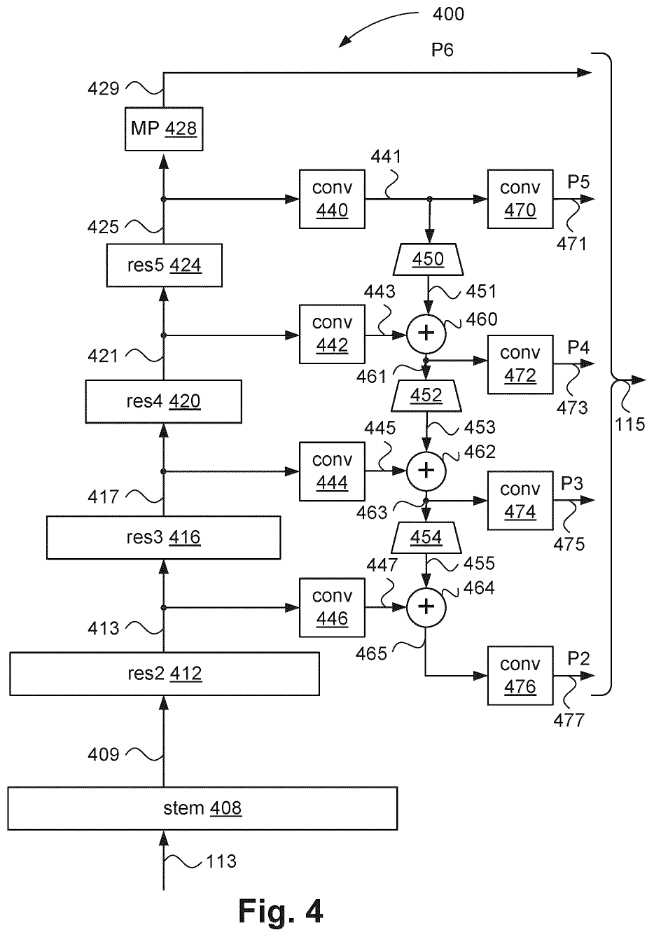

FIG. 4 is a schematic block diagram showing functional modules of an alternative backbone portion 400 of a CNN, which may serve as the CNN backbone 114. The backbone portion 400 implements a residual network with feature pyramid network (‘ResNet FPN’) and is an alternative to the CNN backbone 114. Frame data 113 is input and passes through a stem network 408, a res2 module 412, a res3 module 416, a res4 module 420, a res5 module 424, and a max pool module 428 via tensors 409, 413, 417, 425, with the max pool module 428 producing P6 tensor 429 as output.

The stem network 408 includes a 7×7 convolution with a stride of two (2) and a max pooling operation. The res2 module 412, the res3 module 416, the res4 module 420, and the res5 module 424 perform convolution operations, LeakyReLU activations. Each module 412, 416, 420 and 424 also performs one halving of the resolution of the processed tensors via a stride setting of two. The tensors 413, 417, 421, and 425 are passed to 1×1 lateral convolution modules 446, 444, 442, and 440 respectively. The modules 440, 442, 444, and 446 produce tensors 441, 443, 445, 447, respectively. The tensor 441 is passed to a 3×3 output convolution module 470, which produces an output tensor P5 471. The tensor 441 is also passed to upsampler module 450 to produce an upsampled tensor 451. A summation module 460 sums the tensors 443 and 451 to produce a tensor 461. The tensor 461 is passed to an upsampler module 452 and a 3×3 lateral convolution module 472. The module 472 outputs a P4 tensor 473. The upsampler module 452 produces an upsampled tensor 453. A summation module 462 sums tensors 445 and 453 to produce a tensor 463. The tensor 463 is passed to a 3×3 lateral convolution module 474 and an upsampler module 454. The module 474 outputs a P3 tensor 475. The upsampler module 454 outputs an upsampled tensor 455. A summation module 464 sums the tensors 447 and 455 to produce tensor 465, which is passed to a 3×3 lateral convolution module 476. The module 476 outputs a P2 tensor 477. The upsampler modules 450, 452, and 454 use nearest neighbour interpolation for low computational complexity. The tensors 429, 471, 473, 475, and 477 form the output tensor 115 of the CNN backbone 400. In forming the output tenors 115, the FPN of tensors 429, 471, 473, 475, and 477 provide a hierarchical representation of the frame data including data of feature maps for encoding to the bitstream.

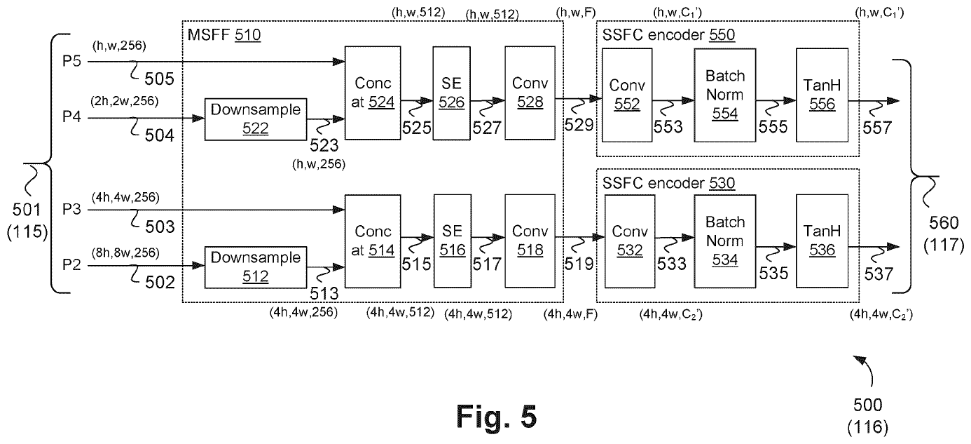

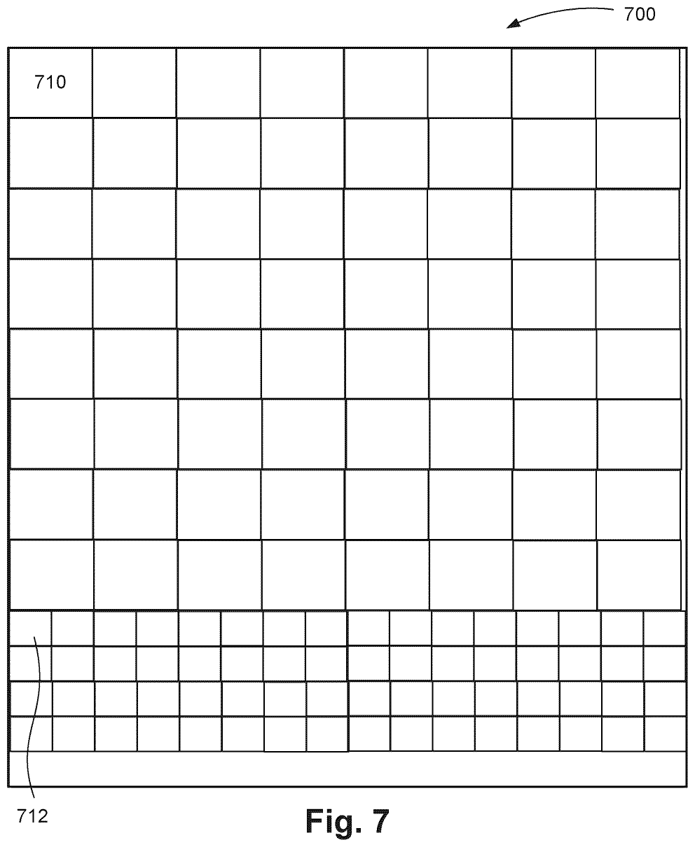

FIG. 5 is a schematic block diagram showing one type of bottleneck encoder 500, which may serve as the bottleneck encoder 116. FIG. 6 shows a method 600 for performing a first portion of a CNN, constricting using the bottleneck encoder 500, and encoding resulting constricted feature maps. FIG. 7 shows a packing arrangement of feature maps from compressed tensors into a monochrome video frame.

The bottleneck encoder 500 receives FPN tensors 501, corresponding to the tensors 115, and operates to restrict the dimensionality of the received tensors to fewer layers and having reduced spatial size. Applying a bottleneck encoder and decoder between the first portion (backbone 114) and the second portion (head 150) of a separated neural network enables a reduction in the spatial area in a frame of packed tensor data. The reduction in spatial area is achieved by using the interface between the bottleneck encoder and the bottleneck decoder as the split point of the first and second portions (114 and 150) of the neural network. The bottleneck encoder 116 acts as additional layers appended to the neural network first portion and the bottleneck decoder 148 acts as additional layers prepended to the neural network second portion.

The sensitivity of the task result to the bottleneck depends on the nature of the task. For object detection, there is less spatial sensitivity and so spatial downsampling of larger layers of the FPN is less detrimental to the resulting mAP. In contrast, segmentation and the resulting segmentation maps are more sensitive to a loss of spatial detail and so benefit from less severe spatial downsampling, especially for spatially larger tensors of the FPN. In the arrangements described, the bottleneck encoder 500 operates at two separate scales, having two different spatial resolutions rather than applying a single scale across all FPN layers. The higher of the two resolution scales is used for larger FPN layers, preserving more detail through the bottleneck encoder 500. The lower of the two resolution scales is used for smaller FPN layers. The input FPN tensors 501 comprise layers P2 502, P3 503, P4 504, and P5 505. The spatial resolutions of the layers P2-P4 (502, 503, 504) are power-of-two multiples of the spatial resolution of P5 505. With P5 505 having width and height (w, h), P2-P4 (502, 503, 504) have dimensions (8 w, 8 h), (4 w, 4 h), (2 w, 2 h), respectively. In other words, respective tensors have resolutions forming an exponential sequence with a doubling in width and height between successive tensors. The layers P2-P5 each have 256 channels.

In the example described above, the inputs P2 to P5 correspond with the hierarchical feature pyramid network outputs (P2 477, P3 475, P4 473 and P5 471) generated by the CNN backbone 400 of FIG. 4. If the CNN backbone is implemented based on FIG. 3A and outputs tensors 329, 326 and 322, the tensors 329, 326 and 322 are derived into two sets of tensors, a first group having one FPN layers 329 and the second group having two FPN layers 322 and 326. The first group, having one FPN layer 329, has the smallest spatial resolution and does not require operation of the MSFF module 510 in the bottleneck encoder 116, with the tensor 329 passed directly to the SSFC encoder 550 as the tensor 529. The second group is processed by the MSFF 510 in the bottleneck encoder 116 with the tensor 326 passed in (input) as the tensor 503 and the tensor 322 passed in as the tensor 502.

The method 600 may be implemented using apparatus such as a configured FPGA, an ASIC, or an ASSP. Alternatively, as described below, the method 600 may be implemented by the source device 110, as one or more software code modules of the application programs 233, under execution of the processor 205. The software code modules of the application programs 233 implementing the method 600 may be resident, for example, in the hard disk drive 210 and/or the memory 206. The method 600 is repeated for each frame of video data produced by the video source 112. The method 600 may be stored on computer-readable storage medium and/or in the memory 206. The method 600 beings at a perform neural network first portion step 610.

At the step 610 the CNN backbone 114, under execution of the processor 205, performs neural network layers corresponding to the first portion of the neural network. The step 610 effectively implements the CNN backbone 114. For example, the CNN layers as described with reference to FIG. 4 may be performed to produce P2-P5 tensors 501 (115). Control in the processor 205 progresses from the step 610 to a select first set of tensors step 615.

The arrangements described effectively divide the tensors produced by CNN backbone 114 into first and second sets of multiple tensors (also referred to as pluralities of tensor), the tensors (or at least one tensor) in each set having different spatial resolution feature maps to one another. At the step 615 bottleneck encoder 116, under execution of the processor 205, selects multiple tensors adjacent among the tensors 501 as the first plurality of tensors, such as two tensors P4 504 and P5 505. The tensors 501 form a hierarchical representation of the frame data 113 that results from application of a FPN to the frame data 113. Use of stride equal to two convolution stages in the FPN, i.e., at modules 412, 416, 420, and 424, results in the spatial dimensions of tensors among the tensors 501 halving in width and height with each respective tensor, when ordered according to decompositional level, for example, from P2 to P5. A degree of inter-layer correlation exists among the layers P2 to P5 of the tensors 501 despite the layers having different spatial resolution. Exploiting inter-layer correlation permits a channel count reduction relative to a concatenation of tensors across layers, provided the tensors are firstly spatially scaled to the same resolution, e.g., the smallest resolution among the tensors to be combined. Combining tensors of greatly differing spatial resolution results in excessive loss of detail in the higher-resolution tensor due to the higher ratio of the downsampling operation. For example, scaling P2 502 to P5 505 requires reducing width and height to one eighth of their former values, for an area reduction to one sixty-fourth of the P2 502 area. For tasks dependent on spatial detail, such as instance segmentation, mAP is degraded. Reductions in mAP due to excessive downsampling of larger layers occurs for detection of small objects where the higher resolution layers are relied upon by the network head. Control in the processor 205 progresses from the step 615 to a select second set of tensors step 620.

At the step 620 a second set of tensors is selected by the processor 205, also comprising tensors of adjacent spatial scale among the P2-P5 layers and containing the remaining tensors among P2-P5 that were not selected at the step 615 as the second plurality of tensors. For example, tensors P2 502 and P3 503 are selected at the step 620. As a result of the steps 615 and 520, the tensors 501 are allocated into two sets of multiple tensors. Control in the processor 205 progresses from the step 620 to a combine first tensors step 630.

At the step 630 a MSFF module 510 (see FIG. 5), under execution of the processor 205, combines each tensor of first set of tensors, i.e., 504, 505, to produce a combined tensor 529. A downsample module 522 operates on the tensor having larger spatial scale, i.e., P4 504 at 2 h, 2 w, 256, downsampling to match the spatial scale of the smaller tensor, i.e., P5 505 at h, w, 256, producing downscaled P5 tensor 523. A concatenation module 524 performs a channel-wise concatenation of the tensors 505 and 523 to produce concatenated tensor 525, of dimensions h, w, 512. The concatenated tensor 525 is passed to a squeeze and excitation (SE) module 526 to produce a tensor 527. The SE module 526 sequentially performs a global pooling, a fully-connected layer with reduction in channel count, a rectified linear unit activation, a second fully-connected layer restoring the channel count, and a sigmoid activation function to produce a scaling tensor. The tensor 525 is scaled according to the scaling tensor to produce the output as the tensor 527. The SE block 526 is capable of being trained to adaptively alter the weighting of different channels in the tensor passed through, based on the first fully-connected layer output. The first fully-connected layer output reduces each feature map for each channel to a single value, which is then passed through the non-linear activation unit (ReLU) to create a conditional representation of the unit, suitable for weighting of other channels, with restoration to the full channel count performed by the second fully-connected layer. The SE block 526 is thus capable of extracting non-linear inter-channel correlation in producing the tensor 527 from the tensor 525, to a greater extent than is possible purely with convolutional (linear) layers. As the tensors 525 and 527 contain 512 channels, a result of the concatenation of two FPN layers, the decorrelation achieved by the SE block 526 spans the two FPN layers P5 and P4.

The tensor 527 is passed to a convolutional layer 528. The convolutional layer 528 implements one or more convolutional layers to produce a first combined tensor 529, with channel count reduced to F channels, typically 256 channels. As a result of the step 630, tensors of two FPN layers are reduced to a single tensor, having the same channel count as the input FPN layer tensors and the spatial resolution of the smaller of the two FPN layer tensors. This dimensionality reduction is achieved with several network layers, and relies upon training the layers (for example layers of 526 and 528) rather than on-the-fly determination of correlation to exploit. Returning to FIG. 6, control in the processor 205 progresses from the step 630 to a combine second tensors step 640.

At the step 640 the MSFF module 510, under execution of the processor 205, combines each tensor of the second tensors, i.e., 502, 503, to produce a combined tensor 519, as described with reference to FIG. 5. Stages performed as part of the step 640 correspond to stages of the step 630 except that the stages are applied to tensors selected at the step 620, rather than tensors selected at the step 615. A downsample module 512 operates on the tensor having larger spatial scale, i.e., P2 502 at 8 h, 8 w, 256, downsampling to match the spatial scale of the smaller tensor, i.e., P3 503 at 4 h, 4 w, 256, producing downscaled P2 tensor 513. A concatenation module 514 performs a channel-wise concatenation of the tensors 503 and 513 to produce concatenated tensor 515, of dimensions 4 h, 4 w, 512. The concatenated tensor 515 is passed to a squeeze and excitation (SE) module 516 to produce a tensor 517. The SE module 516 operates in the same manner as described with reference to the SE module 526. The tensor 517 is passed to a convolutional layer 518. The convolutional layer 518 operates in a similar manner to the convolutional layer 528 to produce a second combined tensor 519, with channel count reduced to F channels, typically 256 channels. As a result of the step 640, tensors of two FPN layers are reduced to a single tensor, having the same channel count as the input FPN layer tensors and a spatial resolution of the smaller of the two FPN layer tensors. The dimensionality reduction is achieved with several network layers, and relies upon training the layers (for example layers of 516 and 518) rather than on-the-fly determination of correlation to exploit. As shown in FIG. 6, control in the processor 205 progresses from the step 640 to a single-scale feature compression (SSFC) encode first tensor step 650.

At the step 650, a SSFC encoder 550 is implemented under execution of the processor 205, as shown in FIG. 5. Operation of the SSFC encoder 550 reduces the dimensionality of the combined tensor 529 to produce a compressed tensor 557. The combined tensor 529 is passed to a convolution layer 552 to produce a tensor 553. The tensor 553 has a channel count reduced from 256 to a smaller value C′, such as 64. The value 96 may also be used for C′, resulting in a larger area requirement for the packed frame, to be described with reference to FIG. 7. The tensor 553 is passed to a batch normalisation module 554 to produce tensor 555. The batch normalised tensor 555 has the same dimensionality as the tensor 553. The tensor 555 is passed to a tanh layer 556. The tanh layer 556 implements a hyperbolic tangent (tanh) layer, as per the layer 536, to produce the compressed tensor 557. The compressed tensor 557 has the same dimensionality as the tensor 553.

Control in the processor 205 progresses from the step 650 to a SSFC encode second tensor step 660, as shown in FIG. 6. At the step 660 a SSFC encoder 530 is implemented under execution of the processor 205 and as described in relation to FIG. 5. The SSFC encoder 530 operates to further reduce the dimensionality of the combined tensor 519 to produce a compressed tensor 537. The combined tensor 519 is passed to a convolution layer 532 to produce a tensor 533, having channel count reduced from 256 to a smaller value C′, such as 64. The tensor 533 is passed to a batch normalisation module 534 to produce tensor 535. The batch normalised tensor 535 has the same dimensionality as the tensor 533. The tensor 535 is passed to a tanh layer 536 to produce the compressed tensor 537. The compressed tensor 537 has the same dimensionality as the tensor 533. Use of a hyperbolic tangent (tanh) layer compresses the dynamic range of values within the tensor 537 to [−1, 1], removing outlier values.

Each of the compressed tensors 557 and 537 provides a unit of information of feature maps of the frame data 113 as obtained using convolutional operations of either (i) the MSFF 510 and the SSFC encoder 550 on the tensors 505 and 504, or (ii) the MSFF 510 and the SSFC encoder 530 on the tensors 503 and 502. The compressed tensors 557 and 537 provide a set of tensors 560 corresponding to the bottleneck encoded tensors 117. On completion of the step 660, control in the processor 205 progresses from the step 660 to a pack compressed tensors step 670 as shown in FIG. 6.

At the step 670 the quantise and pack module 118, under execution of the processor 205, quantises the compressed tensors 537 and 557 and packs the quantised tensors into a single monochrome video frame. An example single monochrome video frame 700 is shown in FIG. 7. The frame 700 corresponds to the frame data 119. The range of the compressed tensors 537 and 557 is [−1, 1] due to use of the tanh activation function at 536 and 556 respectively. The nature of tanh in removing outliers results in a distribution amenable to linear quantisation to the bit depth of the frame 700. Channels of the compressed tensor 537 are packed as feature maps of a particular size, such as a feature map 710 in the frame 700. Channels of the compressed tensor 557 are packed as feature maps of a different size, such as a feature map 712, in the frame 700. One channel of the compressed tensor 537 corresponds to one feature map indicated by one rectangular area, such as the area 710. One channel of the compressed tensor 557 corresponds to one feature map indicated by one rectangular area, such as the area 712. Returning to FIG. 6, control in the processor 205 progresses from the step 670 to a compress frame step 680.

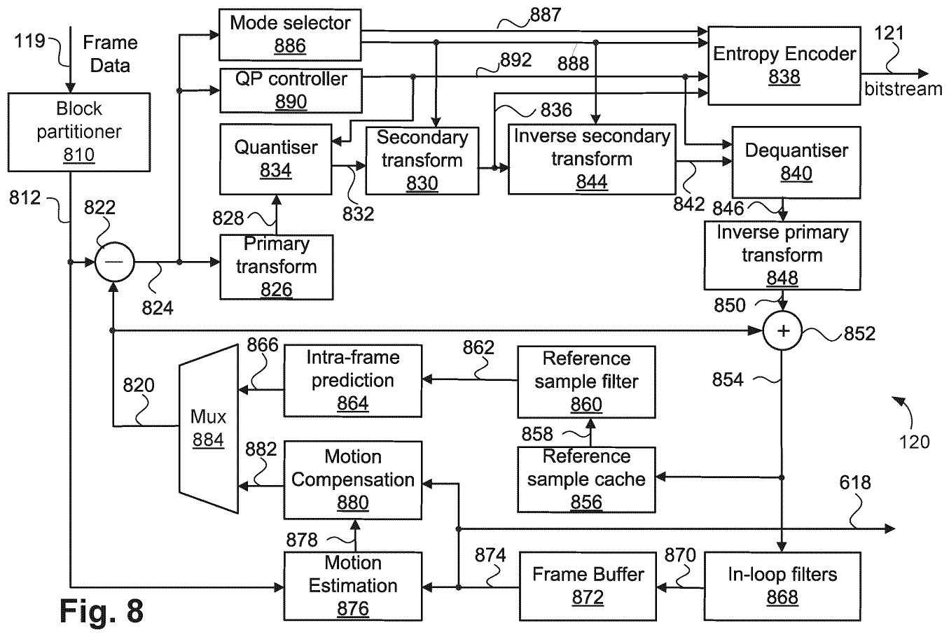

At the step 680 the feature map encoder 120, under execution of the processor 205, encodes the frame 700 to produce the bitstream 121. Operation of the feature map encoder 120 is described with reference to FIG. 8. The method 600 terminates on execution of step 680, with the FPN layers of an image frame 312 reduced in dimensionality and compressed into the video bitstream 121.

FIG. 8 is a schematic block diagram showing functional modules of the video encoder 120, also referred to as a feature map encoder. The video encoder 120 encodes the packed frame 119, shown as frame 700 in the example of FIG. 7, to produce the bitstream 121. Generally, data passes between functional modules within the video encoder 120 in groups of samples or coefficients, such as divisions of blocks into sub-blocks of a fixed size, or as arrays. The video encoder 120 may be implemented using a general-purpose computer system 200, as shown in FIGS. 2A and 2B, where the various functional modules may be implemented by dedicated hardware within the computer system 200, by software executable within the computer system 200 such as one or more software code modules of the software application program 233 resident on the hard disk drive 205 and being controlled in its execution by the processor 205. Alternatively, the video encoder 120 may be implemented by a combination of dedicated hardware and software executable within the computer system 200. The video encoder 120 and the described methods may alternatively be implemented in dedicated hardware, such as one or more integrated circuits performing the functions or sub functions of the described methods. Such dedicated hardware may include graphic processing units (GPUs), digital signal processors (DSPs), application-specific standard products (ASSPs), application-specific integrated circuits (ASICs), field programmable gate arrays (FPGAs) or one or more microprocessors and associated memories. In particular, the video encoder 120 comprises modules 810-890 which may each be implemented as one or more software code modules of the software application program 233.

Although the video encoder 120 of FIG. 8 is an example of a versatile video coding (VVC) video encoding pipeline, other video codecs may also be used to perform the processing stages described herein. The frame data 119 may be in any chroma format and bit depth supported by the profile in use, for example 4:0:0, 4:2:0 for the “Main 10” profile of the VVC standard, at eight (8) to ten (10) bits in sample precision.

A block partitioner 810 firstly divides the frame data 119 into CTUs, generally square in shape and configured such that a particular size for the CTUs is used. The maximum enabled size of the CTUs may be 32×32, 64×64, or 128×128 luma samples for example, configured by a ‘sps_log 2_ctu_size_minus5’ syntax element present in the ‘sequence parameter set’. The CTU size also provides a maximum CU size, as a CTU with no further splitting will contain one CU. The block partitioner 810 further divides each CTU into one or more CBs according to a luma coding tree and a chroma coding tree. The luma channel may also be referred to as a primary colour channel. Each chroma channel may also be referred to as a secondary colour channel. The CBs have a variety of sizes, and may include both square and non-square aspect ratios. However, in the VVC standard, CBs, CUs, PUs, and TUs always have side lengths that are powers of two. Thus, a current CB, represented as 812, is output from the block partitioner 810, progressing in accordance with an iteration over the one or more blocks of the CTU, in accordance with the luma coding tree and the chroma coding tree of the CTU.

The CTUs resulting from the first division of the frame data 119 may be scanned in raster scan order and may be grouped into one or more ‘slices’. A slice may be an ‘intra’ (or ‘I’) slice. An intra slice (I slice) indicates that every CU in the slice is intra predicted. Generally, the first picture in a coded layer video sequence (CLVS) contains only I slices, and is referred to as an ‘intra picture’. The CLVS may contain periodic intra pictures, forming ‘random access points’ (i.e., intermediate frames in a video sequence upon which decoding can commence). Alternatively, a slice may be uni- or bi-predicted (‘P’ or ‘B’ slice, respectively), indicating additional availability of uni- and bi-prediction in the slice, respectively.

The video encoder 120 encodes sequences of pictures according to a picture structure. One picture structure is ‘low delay’, in which case pictures using inter-prediction may only reference pictures occurring previously in the sequence. Low delay enables each picture to be output as soon as the picture is decoded, in addition to being stored for possible reference by a subsequent picture. Another picture structure is ‘random access’, whereby the coding order of pictures differs from the display order. Random access allows inter-predicted pictures to reference other pictures that, although decoded, have not yet been output. A degree of picture buffering is needed so the reference pictures in the future in terms of display order are present in the decoded picture buffer, resulting in a latency of multiple frame.

When a chroma format other than 4:0:0 is in use, in an I slice, the coding tree of each CTU may diverge below the 64×64 level into two separate coding trees, one for luma and another for chroma. Use of separate trees allows different block structure to exist between luma and chroma within a luma 64×64 area of a CTU. For example, a large chroma CB may be collocated with numerous smaller luma CBs and vice versa. In a P or B slice, a single coding tree of a CTU defines a block structure common to luma and chroma. The resulting blocks of the single tree may be intra predicted or inter predicted.

In addition to a division of pictures into slices, pictures may also be divided into ‘tiles’. A tile is a sequence of CTUs covering a rectangular region of a picture. CTU scanning occurs in a raster-scan manner within each tile and progresses from one tile to the next. A slice can be either an integer number of tiles, or an integer number of consecutive rows of CTUs within a given tile.

For each CTU, the video encoder 120 operates in two stages. In the first stage (referred to as a ‘search’ stage), the block partitioner 810 tests various potential configurations of a coding tree. Each potential configuration of a coding tree has associated ‘candidate’ CBs. The first stage involves testing various candidate CBs to select CBs providing relatively high compression efficiency with relatively low distortion. The testing generally involves a Lagrangian optimisation whereby a candidate CB is evaluated based on a weighted combination of rate (i.e., coding cost) and distortion (i.e., error with respect to the input frame data 119). ‘Best’ candidate CBs (i.e., the CBs with the lowest evaluated rate/distortion) are selected for subsequent encoding into the bitstream 121. Included in evaluation of candidate CBs is an option to use a CB for a given area or to further split the area according to various splitting options and code each of the smaller resulting areas with further CBs, or split the areas even further. As a consequence, both the coding tree and the CBs themselves are selected in the search stage.

The video encoder 120 produces a prediction block (PB), indicated by an arrow 820, for each CB, for example, CB 812. The PB 820 is a prediction of the contents of the associated CB 812. A subtracter module 822 produces a difference, indicated as 824 (or ‘residual’, referring to the difference being in the spatial domain), between the PB 820 and the CB 812. The difference 824 is a block-size difference between corresponding samples in the PB 820 and the CB 812. The difference 824 is transformed, quantised and represented as a transform block (TB), indicated by an arrow 836. The PB 820 and associated TB 836 are typically chosen from one of many possible candidate CBs, for example, based on evaluated cost or distortion.

A candidate coding block (CB) is a CB resulting from one of the prediction modes available to the video encoder 120 for the associated PB and the resulting residual. When combined with the predicted PB in the video encoder 120, the TB 836 reduces the difference between a decoded CB and the original CB 812 at the expense of additional signalling in a bitstream.

Each candidate coding block (CB), that is prediction block (PB) in combination with a transform block (TB), thus has an associated coding cost (or ‘rate’) and an associated difference (or ‘distortion’). The distortion of the CB is typically estimated as a difference in sample values, such as a sum of absolute differences (SAD), a sum of squared differences (SSD) or a Hadamard transform applied to the differences. The estimate resulting from each candidate PB may be determined by a mode selector 886 using the difference 824 to determine a prediction mode 887. The prediction mode 887 indicates the decision to use a particular prediction mode for the current CB, for example, intra-frame prediction or inter-frame prediction. Estimation of the coding costs associated with each candidate prediction mode and corresponding residual coding may be performed at significantly lower cost than entropy coding of the residual. Accordingly, a number of candidate modes may be evaluated to determine an optimum mode in a rate-distortion sense even in a real-time video encoder.

Determining an optimum mode in terms of rate-distortion is typically achieved using a variation of Lagrangian optimisation.

Lagrangian or similar optimisation processing can be employed to both select an optimal partitioning of a CTU into CBs (by the block partitioner 810) as well as the selection of a best prediction mode from a plurality of possibilities. Through application of a Lagrangian optimisation process of the candidate modes in the mode selector module 886, the intra prediction mode with the lowest cost measurement is selected as the ‘best’ mode. The lowest cost mode includes the selected secondary transform index 888, which is also encoded in the bitstream 121 by an entropy encoder 838.

In the second stage of operation of the video encoder 120 (referred to as a ‘coding’ stage), an iteration over the determined coding tree(s) of each CTU is performed in the video encoder 120. For a CTU using separate trees, for each 64×64 luma region of the CTU, a luma coding tree is firstly encoded followed by a chroma coding tree. Within the luma coding tree, only luma CBs are encoded and within the chroma coding tree only chroma CBs are encoded. For a CTU using a shared tree, a single tree describes the CUS (i.e., the luma CBs and the chroma CBs) according to the common block structure of the shared tree.

The entropy encoder 838 supports bitwise coding of syntax elements using variable-length and fixed-length codewords, and an arithmetic coding mode for syntax elements. Portions of the bitstream such as ‘parameter sets’, for example, sequence parameter set (SPS) and picture parameter set (PPS) use a combination of fixed-length codewords and variable-length codewords. Slices, also referred to as contiguous portions, have a slice header that uses variable length coding followed by slice data, which uses arithmetic coding. The slice header defines parameters specific to the current slice, such as slice-level quantisation parameter offsets. The slice data includes the syntax elements of each CTU in the slice. Use of variable length coding and arithmetic coding requires sequential parsing within each portion of the bitstream. The portions may be delineated with a start code to form ‘network abstraction layer units’ or ‘NAL units’. Arithmetic coding is supported using a context-adaptive binary arithmetic coding process.

Arithmetically coded syntax elements consist of sequences of one or more ‘bins’. Bins, like bits, have a value of ‘0’ or ‘1’. However, bins are not encoded in the bitstream 121 as discrete bits. Bins have an associated predicted (or ‘likely’ or ‘most probable’) value and an associated probability, known as a ‘context’. When the actual bin to be coded matches the predicted value, a ‘most probable symbol’ (MPS) is coded. Coding a most probable symbol is relatively inexpensive in terms of consumed bits in the bitstream 121, including costs that amount to less than one discrete bit. When the actual bin to be coded mismatches the likely value, a ‘least probable symbol’ (LPS) is coded. Coding a least probable symbol has a relatively high cost in terms of consumed bits. The bin coding techniques enable efficient coding of bins where the probability of a ‘0’ versus a ‘1’ is skewed. For a syntax element with two possible values (i.e., a ‘flag’), a single bin is adequate. For syntax elements with many possible values, a sequence of bins is needed.

The presence of later bins in the sequence may be determined based on the value of earlier bins in the sequence. Additionally, each bin may be associated with more than one context. The selection of a particular context may be dependent on earlier bins in the syntax element, the bin values of neighbouring syntax elements (i.e., those from neighbouring blocks) and the like. Each time a context-coded bin is encoded, the context that was selected for that bin (if any) is updated in a manner reflective of the new bin value. As such, the binary arithmetic coding scheme is said to be adaptive.

Also supported by the entropy encoder 838 are bins that lack a context, referred to as “bypass bins”. Bypass bins are coded assuming an equiprobable distribution between a ‘0’ and a ‘1’. Thus, each bin has a coding cost of one bit in the bitstream 121. The absence of a context saves memory and reduces complexity, and thus bypass bins are used where the distribution of values for the particular bin is not skewed. One example of an entropy coder employing context and adaption is known in the art as CABAC (context adaptive binary arithmetic coder) and many variants of this coder have been employed in video coding.

The entropy encoder 838 encodes a quantisation parameter 892 and, if in use for the current CB, the LFNST index 888, using a combination of context-coded and bypass-coded bins. The quantisation parameter 892 is encoded using a ‘delta QP’ generated by a QP controller module 890. The delta QP is signalled at most once in each area known as a ‘quantisation group’. The quantisation parameter 892 is applied to residual coefficients of the luma CB. An adjusted quantisation parameter is applied to the residual coefficients of collocated chroma CBs. The adjusted quantisation parameter may include mapping from the luma quantisation parameter 892 according to a mapping table and a CU-level offset, selected from a list of offsets. The secondary transform index 888 is signalled when the residual associated with the transform block includes significant residual coefficients only in those coefficient positions subject to transforming into primary coefficients by application of a secondary transform.

Residual coefficients of each TB associated with a CB are coded using a residual syntax. The residual syntax is designed to efficiently encode coefficients with low magnitudes, using mainly arithmetically coded bins to indicate significance of coefficients, along with lower-valued magnitudes and reserving bypass bins for higher magnitude residual coefficients. Accordingly, residual blocks comprising very low magnitude values and sparse placement of significant coefficients are efficiently compressed. Moreover, two residual coding schemes are present. A regular residual coding scheme is optimised for TBs with significant coefficients predominantly located in the upper-left corner of the TB, as is seen when a transform is applied. A transform-skip residual coding scheme is available for TBs where a transform is not performed and is able to efficiently encode residual coefficients regardless of their distribution throughout the TB.

A multiplexer module 884 outputs the PB 820 from an intra-frame prediction module 864 according to the determined best intra prediction mode, selected from the tested prediction mode of each candidate CB. The candidate prediction modes need not include every conceivable prediction mode supported by the video encoder 120. Intra prediction falls into three types, first, “DC intra prediction”, which involves populating a PB with a single value representing the average of nearby reconstructed samples; second, “planar intra prediction”, which involves populating a PB with samples according to a plane, with a DC offset and a vertical and horizontal gradient being derived from nearby reconstructed neighbouring samples. The nearby reconstructed samples typically include a row of reconstructed samples above the current PB, extending to the right of the PB to an extent and a column of reconstructed samples to the left of the current PB, extending downwards beyond the PB to an extent; and, third, “angular intra prediction”, which involves populating a PB with reconstructed neighbouring samples filtered and propagated across the PB in a particular direction (or ‘angle’). In VVC, sixty-five (65) angles are supported, with rectangular blocks able to utilise additional angles, not available to square blocks, to produce a total of eighty-seven (87) angles.

A fourth type of intra prediction is available to chroma PBs, whereby the PB is generated from collocated luma reconstructed samples according to a ‘cross-component linear model’ (CCLM) mode. Three different CCLM modes are available, each mode using a different model derived from the neighbouring luma and chroma samples. The derived model is used to generate a block of samples for the chroma PB from the collocated luma samples. Luma blocks may be intra predicted using a matrix multiplication of the reference samples using one matrix selected from a predefined set of matrices. This matrix intra prediction (MIP) achieves gain by using matrices trained on a large set of video data, with the matrices representing relationships between reference samples and a predicted block that are not easily captured in angular, planar, or DC intra prediction modes.

The module 864 may also produce a prediction unit by copying a block from nearby the current frame using an ‘intra block copy’ (IBC) method. The location of the reference block is constrained to an area equivalent to one CTU, divided into 64×64 regions known as VPDUs, with the area covering the processed VPDUs of the current CTU and VPDUs of the previous CTU(s) within each row or CTUs and within each slice or tile up to the area limit corresponding to one 128×128 luma samples, regardless of the configured CTU size for the bitstream. This area is known as an ‘IBC virtual buffer’ and limits the IBC reference area, thus limiting the required storage. The IBC buffer is populated with reconstructed samples 854 (i.e., prior to loop filtering), and so a separate buffer to the frame buffer 872 is needed. When the CTU size is 128×128 the virtual buffer includes samples only from the CTU adjacent and to the left of the current CTU. When the CTU size is 32×32 or 64×64 the virtual buffer includes CTUs from up to the four or sixteen CTUs to the left of the current CTU. Regardless of the CTU size, access to neighbouring CTUs for obtaining samples for IBC reference blocks is constrained by boundaries such as edges of pictures, slices, or tiles. Especially for feature maps of FPN layers having smaller dimensions, use of a CTU size such as 32×32 or 64×64 results in a reference area more aligned to cover a set of previous feature maps. Where feature map placement is ordered based on SAD, SSE or other difference metric, access to similar feature maps for IBC prediction offers coding efficient advantage.

The residual for a predicted block when encoding feature map data is different to the residual seen for natural video. Such natural video is typically captured by an imaging sensor, or screen content, as generally seen in operating system user interfaces and the like. Feature map residuals tend to contain much detail, which is amenable to transform skip coding more than predominantly low-frequency coefficients of various transforms. Experiments show that the feature map residual has enough local similarity to benefit from transform coding. However, the distribution of feature map residual coefficients is not clustered towards the DC (top-left) coefficient of a transform block. In other words, sufficient correlation exists for a transform to show gain when encoding feature map data and this is true also for when intra block copy is used to produce prediction blocks for the feature map data. Accordingly, a Hadamard cost estimate may be used when evaluating residuals resulting from candidate block vectors for intra block copy when encoding feature map data, instead of relying solely on a SAD or SSD cost estimate. SAD or SSD cost estimates tend to select block vectors with residuals more amenable to transform skip coding and may miss block vectors with residuals that would be compactly encoded using transforms. The multiple transform selection (MTS) tool of the VVC standard may be used when encoding feature map data so that, in addition to the DCT-2 transform, combinations of DST-7 and DCT-8 transforms are available horizontally and vertically for residual encoding.

An intra-predicted luma coding block may be partitioned into a set of equal-sized prediction blocks, either vertically or horizontally, which each block having a minimum area of sixteen (16) luma samples. This intra sub-partition (ISP) approach enables separate transform blocks to contribute to prediction block generation from one sub-partition to the next sub-partition in the luma coding block, improving compression efficiency.

Where previously reconstructed neighbouring samples are unavailable, for example at the edge of the frame, a default half-tone value of one half the range of the samples is used. For example, for 10-bit video a value of five-hundred and twelve (512) is used. As no previous samples are available for a CB located at the top-left position of a frame, angular and planar intra-prediction modes produce the same output as the DC prediction mode (i.e. a flat plane of samples having the half-tone value as magnitude).

For inter-frame prediction a prediction block 882 is produced using samples from one or two frames preceding the current frame in the coding order frames in the bitstream by a motion compensation module 880 and output as the PB 820 by the multiplexer module 884. Moreover, for inter-frame prediction, a single coding tree is typically used for both the luma channel and the chroma channels. The order of coding frames in the bitstream may differ from the order of the frames when captured or displayed. When one frame is used for prediction, the block is said to be ‘uni-predicted’ and has one associated motion vector. When two frames are used for prediction, the block is said to be ‘bi-predicted’ and has two associated motion vectors. For a P slice, each CU may be intra predicted or uni-predicted. For a B slice, each CU may be intra predicted, uni-predicted, or bi-predicted.

Frames are typically coded using a ‘group of pictures’ (GOP) structure, enabling a temporal hierarchy of frames. Frames may be divided into multiple slices, each of which encodes a portion of the frame. A temporal hierarchy of frames allows a frame to reference a preceding and a subsequent picture in the order of displaying the frames. The images are coded in the order necessary to ensure the dependencies for decoding each frame are met. An affine inter prediction mode is available where instead of using one or two motion vectors to select and filter reference sample blocks for a prediction unit, the prediction unit is divided into multiple smaller blocks and a motion field is produced so each smaller block has a distinct motion vector. The motion field uses the motion vectors of nearby points to the prediction unit as ‘control points’. Affine prediction allows coding of motion different to translation with less need to use deeply split coding trees. A bi-prediction mode available to VVC performs a geometric blend of the two reference blocks along a selected axis, with angle and offset from the centre of the block signalled. This geometric partitioning mode (“GPM”) allows larger coding units to be used along the boundary between two objects, with the geometry of the boundary coded for the coding unit as an angle and centre offset. Motion vector differences, instead of using cartesian (x, y) offset, may be coded as a direction (up/down/left/right) and a distance, with a set of power-of-two distances supported. The motion vector predictor is obtained from a neighbouring block (‘merge mode’) as if no offset is applied. The current block will share the same motion vector as the selected neighbouring block.

The samples are selected according to a motion vector 878 and reference picture index. The motion vector 878 and reference picture index applies to all colour channels and thus inter prediction is described primarily in terms of operation upon PUs rather than PBs. The decomposition of each CTU into one or more inter-predicted blocks is described with a single coding tree. Inter prediction methods may vary in the number of motion parameters and their precision. Motion parameters typically comprise a reference frame index, indicating which reference frame(s) from lists of reference frames are to be used plus a spatial translation for each of the reference frames, but may include more frames, special frames, or complex affine parameters such as scaling and rotation. In addition, a pre-determined motion refinement process may be applied to generate dense motion estimates based on referenced sample blocks.

Having determined and selected the PB 820 and subtracted the PB 820 from the original sample block at the subtractor 822, a residual with lowest coding cost, represented as 824, is obtained and subjected to lossy compression. The lossy compression process comprises the steps of transformation, quantisation and entropy coding. A forward primary transform module 826 applies a forward transform to the difference 824, converting the difference 824 from the spatial domain to the frequency domain, and producing primary transform coefficients represented by an arrow 828. The largest primary transform size in one dimension is either a 32-point DCT-2 or a 64-point DCT-2 transform, configured by a ‘sps_max_luma_transform_size_64_flag’ in the sequence parameter set. If the CB being encoded is larger than the largest supported primary transform size expressed as a block size (e.g. 64×64 or 32×32), the primary transform 826 is applied in a tiled manner to transform all samples of the difference 824. Where a non-square CB is used, tiling is also performed using the largest available transform size in each dimension of the CB. For example, when a maximum transform size of thirty-two (32) is used, a 64×16 CB uses two 32×16 primary transforms arranged in a tiled manner. When a CB is larger in size than the maximum supported transform size, the CB is filled with TBs in a tiled manner. For example, a 128×128 CB with 64-pt transform maximum size is filled with four 64×64 TBs in a 2×2 arrangement. A 64×128 CB with a 32-pt transform maximum size is filled with eight 32×32 TBs in a 2×4 arrangement.

Application of the transform 826 results in multiple TBs for the CB. Where each application of the transform operates on a TB of the difference 824 larger than 32×32, e.g. 64×64, all resulting primary transform coefficients 828 outside of the upper-left 32×32 area of the TB are set to zero (i.e., discarded). The remaining primary transform coefficients 828 are passed to a quantiser module 834. The primary transform coefficients 828 are quantised according to the quantisation parameter 892 associated with the CB to produce primary transform coefficients 832. In addition to the quantisation parameter 892, the quantiser module 834 may also apply a ‘scaling list’ to allow non-uniform quantisation within the TB by further scaling residual coefficients according to their spatial position within the TB. The quantisation parameter 892 may differ for a luma CB versus each chroma CB. The primary transform coefficients 832 are passed to a forward secondary transform module 830 to produce the transform coefficients represented by the arrow 836 by performing either a non-separable secondary transform (NSST) operation or bypassing the secondary transform. The forward primary transform is typically separable, transforming a set of rows and then a set of columns of each TB. The forward primary transform module 826 uses either a type-II discrete cosine transform (DCT-2) in the horizontal and vertical directions, or bypass of the transform horizontally and vertically, or combinations of a type-VII discrete sine transform (DST-7) and a type-VIII discrete cosine transform (DCT-8) in either horizontal or vertical directions for luma TBs not exceeding 16 samples in width and height. Use of combinations of a DST-7 and DCT-8 is referred to as ‘multi transform selection set’ (MTS) in the VVC standard.

The forward secondary transform of the module 830 is generally a non-separable transform, which is only applied for the residual of intra-predicted CUs and may nonetheless also be bypassed. The forward secondary transform operates either on sixteen (16) samples (arranged as the upper-left 4×4 sub-block of the primary transform coefficients 828) or forty-eight (48) samples (arranged as three 4×4 sub-blocks in the upper-left 8×8 coefficients of the primary transform coefficients 828) to produce a set of secondary transform coefficients. The set of secondary transform coefficients may be fewer in number than the set of primary transform coefficients from which they are derived. Due to application of the secondary transform to only a set of coefficients adjacent to each other and including the DC coefficient, the secondary transform is referred to as a ‘low frequency non-separable secondary transform’ (LFNST). Such secondary transforms may be obtained through a training process and due to their non-separable nature and trained origin, exploit additional redundancy in the residual signal not able to be captured by separable transforms such as variants of DCT and DST. Moreover, when the LFNST is applied, all remaining coefficients in the TB are zero, both in the primary transform domain and the secondary transform domain.

The quantisation parameter 892 is constant for a given TB and thus results in a uniform scaling for the production of residual coefficients in the primary transform domain for a TB. The quantisation parameter 892 may vary periodically with a signalled ‘delta quantisation parameter’. The delta quantisation parameter (delta QP) is signalled once for CUs contained within a given area, referred to as a ‘quantisation group’. If a CU is larger than the quantisation group size, delta QP is signalled once with one of the TBs of the CU. That is, the delta QP is signalled by the entropy encoder 838 once for the first quantisation group of the CU and not signalled for any subsequent quantisation groups of the CU. A non-uniform scaling is also possible by application of a ‘quantisation matrix’, whereby the scaling factor applied for each residual coefficient is derived from a combination of the quantisation parameter 892 and the corresponding entry in a scaling matrix. The scaling matrix may have a size that is smaller than the size of the TB, and when applied to the TB a nearest neighbour approach is used to provide scaling values for each residual coefficient from a scaling matrix smaller in size than the TB size. The residual coefficients 836 are supplied to the entropy encoder 838 for encoding in the bitstream 121. Typically, the residual coefficients of each TB with at least one significant residual coefficient of the TU are scanned to produce an ordered list of values, according to a scan pattern. The scan pattern generally scans the TB as a sequence of 4×4 ‘sub-blocks’, providing a regular scanning operation at the granularity of 4×4 sets of residual coefficients, with the arrangement of sub-blocks dependent on the size of the TB. The scan within each sub-block and the progression from one sub-block to the next typically follow a backward diagonal scan pattern. Additionally, the quantisation parameter 892 is encoded into the bitstream 121 using a delta QP syntax element, and a slice QP for the initial value in a given slice or subpicture and the secondary transform index 888 is encoded in the bitstream 121.

As described above, the video encoder 120 needs access to a frame representation corresponding to the decoded frame representation seen in the video decoder. Thus, the residual coefficients 836 are passed through an inverse secondary transform module 844, operating in accordance with the secondary transform index 888 to produce intermediate inverse transform coefficients, represented by an arrow 842. The intermediate inverse transform coefficients 842 are inverse quantised by a dequantiser module 840 according to the quantisation parameter 892 to produce inverse transform coefficients, represented by an arrow 846. The dequantiser module 840 may also perform an inverse non-uniform scaling of residual coefficients using a scaling list, corresponding to the forward scaling performed in the quantiser module 834. The inverse transform coefficients 846 are passed to an inverse primary transform module 848 to produce residual samples, represented by an arrow 850, of the TU. The inverse primary transform module 848 applies DCT-2 transforms horizontally and vertically, constrained by the maximum available transform size as described with reference to the forward primary transform module 826. The types of inverse transform performed by the inverse secondary transform module 844 correspond with the types of forward transform performed by the forward secondary transform module 830. The types of inverse transform performed by the inverse primary transform module 848 correspond with the types of primary transform performed by the primary transform module 826. A summation module 852 adds the residual samples 850 and the PU 820 to produce reconstructed samples (indicated by the arrow 854) of the CU.

The reconstructed samples 854 are passed to a reference sample cache 856 and an in-loop filters module 868. The reference sample cache 856, typically implemented using static RAM on an ASIC to avoid costly off-chip memory access, provides minimal sample storage needed to satisfy the dependencies for generating intra-frame PBs for subsequent CUs in the frame. The minimal dependencies typically include a ‘line buffer’ of samples along the bottom of a row of CTUs, for use by the next row of CTUs and column buffering the extent of which is set by the height of the CTU. The reference sample cache 856 supplies reference samples (represented by an arrow 858) to a reference sample filter 860. The sample filter 860 applies a smoothing operation to produce filtered reference samples (indicated by an arrow 862). The filtered reference samples 862 are used by an intra-frame prediction module 864 to produce an intra-predicted block of samples, represented by an arrow 866. For each candidate intra prediction mode the intra-frame prediction module 864 produces a block of samples, that is 866. The block of samples 866 is generated by the module 864 using techniques such as DC, planar or angular intra prediction. The block of samples 866 may also be produced using a matrix-multiplication approach with neighbouring reference sample as input and a matrix selected from a set of matrices by the video encoder 120, with the selected matrix signalled in the bitstream 121 using an index to identify which matrix of the set of matrices is to be used by the video decoder 144.

The in-loop filters module 868 applies several filtering stages to the reconstructed samples 854. The filtering stages include a ‘deblocking filter’ (DBF) which applies smoothing aligned to the CU boundaries to reduce artefacts resulting from discontinuities. Another filtering stage present in the in-loop filters module 868 is an ‘adaptive loop filter’ (ALF), which applies a Wiener-based adaptive filter to further reduce distortion. A further available filtering stage in the in-loop filters module 868 is a ‘sample adaptive offset’ (SAO) filter. The SAO filter operates by firstly classifying reconstructed samples into one or multiple categories and, according to the allocated category, applying an offset at the sample level.

Filtered samples, represented by an arrow 870, are output from the in-loop filters module 868. The filtered samples 870 are stored in the frame buffer 872. The frame buffer 872 typically has the capacity to store several (e.g., up to sixteen (16)) pictures and thus is stored in the memory 206. The frame buffer 872 is not typically stored using on-chip memory due to the large memory consumption required. As such, access to the frame buffer 872 is costly in terms of memory bandwidth. The frame buffer 872 provides reference frames (represented by an arrow 874) to a motion estimation module 876 and the motion compensation module 880.

The motion estimation module 876 estimates a number of ‘motion vectors’ (indicated as 878), each being a Cartesian spatial offset from the location of the present CB, referencing a block in one of the reference frames in the frame buffer 872. A filtered block of reference samples (represented as 882) is produced for each motion vector. The filtered reference samples 882 form further candidate modes available for potential selection by the mode selector 886. Moreover, for a given CU, the PU 820 may be formed using one reference block (‘uni-predicted’) or may be formed using two reference blocks (‘bi-predicted’). For the selected motion vector, the motion compensation module 880 produces the PB 820 in accordance with a filtering process supportive of sub-pixel accuracy in the motion vectors. As such, the motion estimation module 876 (which operates on many candidate motion vectors) may perform a simplified filtering process compared to that of the motion compensation module 880 (which operates on the selected candidate only) to achieve reduced computational complexity. When the video encoder 120 selects inter prediction for a CU the motion vector 878 is encoded into the bitstream 121.

Although the video encoder 120 of FIG. 8 is described with reference to versatile video coding (VVC), other video coding standards or implementations may also employ the processing stages of modules 810-890. The frame data 119 (and bitstream 121) may also be read from (or written to) memory 206, the hard disk drive 210, a CD-ROM, a Blu-ray Disk™ or other computer readable storage medium. Additionally, the frame data 119 (and bitstream 121) may be received from (or transmitted to) an external source, such as a server connected to the communications network 220 or a radio-frequency receiver. The communications network 220 may provide limited bandwidth, necessitating the use of rate control in the video encoder 120 to avoid saturating the network at times when the frame data 119 is difficult to compress. Moreover, the bitstream 121 may be constructed from one or more slices, representing spatial sections (collections of CTUs) of the frame data 119, produced by one or more instances of the video encoder 120, operating in a co-ordinated manner under control of the processor 205. The bitstream 121 may also contain one slice that corresponds to one subpicture to be output as a collection of subpictures forming one picture, each being independently encodable and independently decodable with respect to any of the other slices or subpictures in the picture.

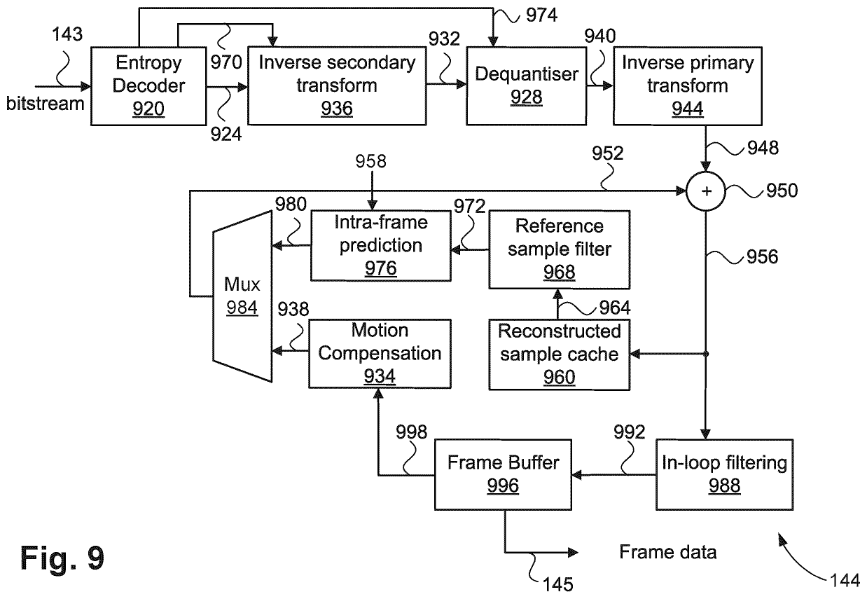

The video decoder 144, also referred to as a feature map decoder, is shown in FIG. 9. Although the video decoder 144 of FIG. 9 is an example of a versatile video coding (VVC) video decoding pipeline, other video codecs may also be used to perform the processing stages described herein. As shown in FIG. 9, the bitstream 143 is input to the video decoder 144. The bitstream 143 may be read from memory 206, the hard disk drive 210, a CD-ROM, a Blu-ray Disk™ or other non-transitory computer readable storage medium. Alternatively, the bitstream 143 may be received from an external source such as a server connected to the communications network 220 or a radio-frequency receiver. The bitstream 143 contains encoded syntax elements representing the captured frame data to be decoded.

The bitstream 143 is input to an entropy decoder module 920. The entropy decoder module 920 extracts syntax elements from the bitstream 143 by decoding sequences of ‘bins’ and passes the values of the syntax elements to other modules in the video decoder 144. The entropy decoder module 920 uses variable-length and fixed length decoding to decode SPS, PPS or slice header an arithmetic decoding engine to decode syntax elements of the slice data as a sequence of one or more bins. Each bin may use one or more ‘contexts’, with a context describing probability levels to be used for coding a ‘one’ and a ‘zero’ value for the bin. Where multiple contexts are available for a given bin, a ‘context modelling’ or ‘context selection’ step is performed to choose one of the available contexts for decoding the bin. The process of decoding bins forms a sequential feedback loop, thus each slice may be decoded in the slice's entirety by a given entropy decoder 920 instance. A single (or few) high-performing entropy decoder 920 instances may decode all slices or subpictures for a frame or picture from the bitstream 143 multiple lower-performing entropy decoder 920 instances may concurrently decode the slices for a frame from the bitstream 143.

The entropy decoder module 920 applies an arithmetic coding algorithm, for example ‘context adaptive binary arithmetic coding’ (CABAC), to decode syntax elements from the bitstream 143. The decoded syntax elements are used to reconstruct parameters within the video decoder 144. Parameters include residual coefficients (represented by an arrow 924), a quantisation parameter 974, a secondary transform index 970, and mode selection information such as an intra prediction mode (represented by an arrow 958). The mode selection information also includes information such as motion vectors, and the partitioning of each CTU into one or more CBs. Parameters are used to generate PBs, typically in combination with sample data from previously decoded CBs.

The residual coefficients 924 are passed to an inverse secondary transform module 936 where either a secondary transform is applied or no operation is performed (bypass) according to a secondary transform index. The inverse secondary transform module 936 produces reconstructed transform coefficients 932, that is primary transform domain coefficients, from secondary transform domain coefficients. The reconstructed transform coefficients 932 are input to a dequantiser module 928. The dequantiser module 928 performs inverse quantisation (or ‘scaling’) on the residual coefficients 932, that is, in the primary transform coefficient domain, to create reconstructed intermediate transform coefficients, represented by an arrow 940, according to the quantisation parameter 974. The dequantiser module 928 may also apply a scaling matrix to provide non-uniform dequantization within the TB, corresponding to operation of the dequantiser module 840. Should use of a non-uniform inverse quantisation matrix be indicated in the bitstream 143, the video decoder 144 reads a quantisation matrix from the bitstream 143 as a sequence of scaling factors and arranges the scaling factors into a matrix. The inverse scaling uses the quantisation matrix in combination with the quantisation parameter to create the reconstructed intermediate transform coefficients 940.

The reconstructed transform coefficients 940 are passed to an inverse primary transform module 944. The module 944 transforms the coefficients 940 from the frequency domain back to the spatial domain. The inverse primary transform module 944 applies inverse DCT-2 transforms horizontally and vertically, constrained by the maximum available transform size as described with reference to the forward primary transform module 726. The result of operation of the module 944 is a block of residual samples, represented by an arrow 948. The block of residual samples 948 is equal in size to the corresponding CB. The residual samples 948 are supplied to a summation module 950.

At the summation module 950 the residual samples 948 are added to a decoded PB (represented as 952) to produce a block of reconstructed samples, represented by an arrow 956. The reconstructed samples 956 are supplied to a reconstructed sample cache 960 and an in-loop filtering module 988. The in-loop filtering module 988 produces reconstructed blocks of frame samples, represented as 992. The frame samples 992 are written to a frame buffer 996.

The reconstructed sample cache 960 operates similarly to the reconstructed sample cache 856 of the video encoder 120. The reconstructed sample cache 960 provides storage for reconstructed samples needed to intra predict subsequent CBs without the memory 206 (e.g., by using the data 232 instead, which is typically on-chip memory). Reference samples, represented by an arrow 964, are obtained from the reconstructed sample cache 960 and supplied to a reference sample filter 968 to produce filtered reference samples indicated by arrow 972. The filtered reference samples 972 are supplied to an intra-frame prediction module 976. The module 976 produces a block of intra-predicted samples, represented by an arrow 980, in accordance with the intra prediction mode parameter 958 signalled in the bitstream 143 and decoded by the entropy decoder 920. The intra prediction module 976 supports the modes of the module 764, including IBC and MIP. The block of samples 980 is generated using modes such as DC, planar or angular intra prediction.

When the prediction mode of a CB is indicated to use intra prediction in the bitstream 143, the intra-predicted samples 980 form the decoded PB 952 via a multiplexor module 984. Intra prediction produces a prediction block (PB) of samples, which is a block in one colour component, derived using ‘neighbouring samples’ in the same colour component. The neighbouring samples are samples adjacent to the current block and by virtue of being preceding in the block decoding order have already been reconstructed. Where luma and chroma blocks are collocated, the luma and chroma blocks may use different intra prediction modes. However, the two chroma CBs share the same intra prediction mode.

When the prediction mode of the CB is indicated to be inter prediction in the bitstream 143, a motion compensation module 934 produces a block of inter-predicted samples, represented as 938. The block of inter-predicted samples 938 are produced using a motion vector, decoded from the bitstream 143 by the entropy decoder 920, and reference frame index to select and filter a block of samples 998 from the frame buffer 996. The block of samples 998 is obtained from a previously decoded frame stored in the frame buffer 996. For bi-prediction, two blocks of samples are produced and blended together to produce samples for the decoded PB 952. The frame buffer 996 is populated with filtered block data 992 from the in-loop filtering module 988. As with the in-loop filtering module 868 of the video encoder 120, the in-loop filtering module 988 applies any of the DBF, the ALF and SAO filtering operations. Generally, the motion vector is applied to both the luma and chroma channels, although the filtering processes for sub-sample interpolation in the luma and chroma channel are different. Frames from the frame buffer 996 are output as decoded frames 145.

Not shown in FIGS. 8 and 9 is a module for pre-processing video prior to encoding and postprocessing video after decoding to shift sample values such that a more uniform usage of the range of sample values within each chroma channel is achieved. A multi-segment linear model is derived in the video encoder 120 and signalled in the bitstream for use by the video decoder 804 to undo the sample shifting. This linear-model chroma scaling (LMCS) tool provides compression benefit for particular colour spaces and content that have some nonuniformity, especially utilisation of a limited range, in their utilisation of the sample space that may result in higher quality loss from application of quantisation.

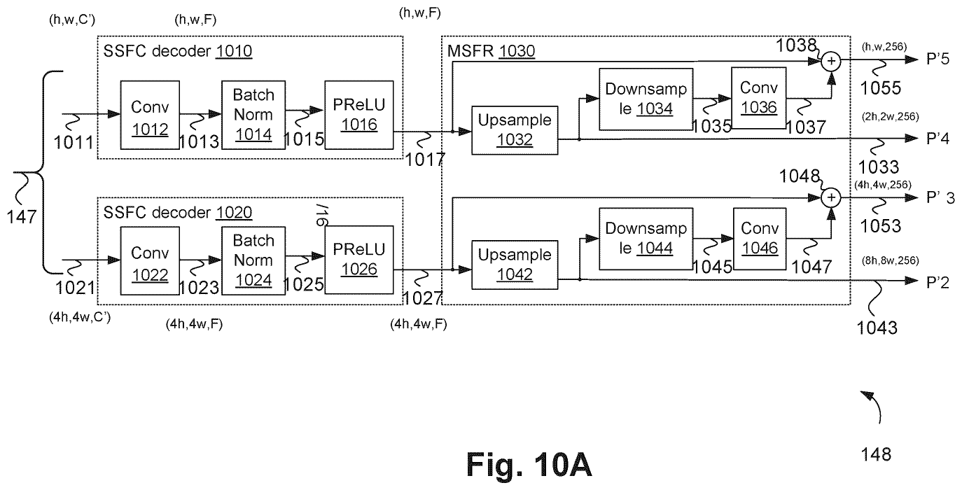

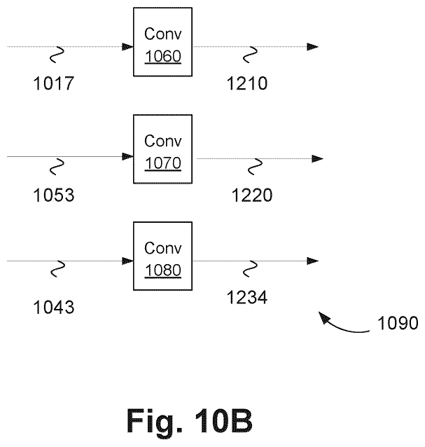

FIG. 10A is a schematic block diagram showing a cross-layer tensor inverse bottleneck 148 for restoring tensor dimensionality after compression. FIG. 11 shows a method 1100 for decoding a bitstream, reconstructing decorrelated feature maps, and performing a second portion of the CNN.

The method 1100 may be implemented using apparatus such as a configured FPGA, an ASIC, or an ASSP. Alternatively, as described below, the method 1100 may be implemented by the destination device 140, as one or more software code modules of the application programs 233, under execution of the processor 205. The software code modules of the application programs 233 implementing the method 1100 may be resident, for example, in the hard disk drive 210 and/or the memory 206. The method 1100 is repeated for each frame of compressed data in the bitstream 143. The method 1100 may be stored on computer-readable storage medium and/or in the memory 206. The method 1100 beings at a decode bitstream step 1110.

At the step 1110 the video decoder 144, under execution of the processor 205, decodes one frame 145 from the bitstream 143 as described with reference to FIG. 9. The frame 145 contains feature maps packed as described with reference to FIG. 7. Control in the processor 205 progresses from the step 1110 to an extract first combined tensor step 1120.

At the step 1120 the unpack and inverse quantise module 146 extracts feature maps for the first combined tensor, e.g., 557, from the decoded frame 145. The extracted feature maps are inverse quantised from the integer domain to the floating-point domain at step 1120. The inverse quantised feature maps generated by operation of step 1120 are shown as tensor 1011 in FIG. 10A. Control in the processor 205 progresses from the step 1120 to an extract second combined tensor step 1130.

At the step 1130 the unpack and inverse quantise module 146 extracts feature maps for the second combined tensor, e.g., 537, from the frame 145. The extracted feature maps are inverse quantised from the integer domain to the floating-point domain at step 1130. The inverse quantised feature maps generated by operation of step 1130 are shown as tensor 1021 in FIG. 10A. The inverse quantised feature 1011 and 1021 correspond to the decoded bottleneck (compressed) tensors 147, as shown in FIG. 10A. Control in the processor 205 progresses from the step 1130 to an SSFC decode first combined tensor step 1140, as shown in FIG. 11.

Steps 1110, 1120 and 1130 operate to decode a frame of the bitstream to obtain two units of information for the frame. The tensor 1011 provides a first unit of information and the tensor 1021 the second unit of information. Each unit of information corresponds to feature maps of the frame encoded in the bitstream.

At the step 1140, an SSFC decoder 1010 is implemented under execution of the processor 205. The SSFC decoder performs neural network layers to decompress the first decoded compressed tensor 1011 to produce a first decoded combined tensor 1017. A convolutional layer 1012 receives the tensor 1011 having C′=64 channels and outputs a tensor 1013 having F=256 channels. The tensor 1013 is passed to a batch normalisation layer 1014. The batch normalisation layer outputs a tensor 1015. The tensor 1015 is passed to a parameterised leaky rectified linear (PReLU) layer 1016. The PRELU layer 1016 outputs the tensor 1017. Returning to FIG. 11, control in the processor 205 progresses from the step 1140 to an SSFC decode second combined tensor step 1150.

At the step 1150, an SSFC decoder 1020 is implemented under execution of the processor 205. The SSFC performs neural network layers to decompress the second decoded compressed tensor 1021 to produce a second decoded combined tensor 1027. A convolutional layer 1022 receives the tensor 1021 having C′=64 channels and outputs a tensor 1023 having F=256 channels. The tensor 1023 is passed to a batch normalisation layer 1024. The batch normalisation layer 1024 outputs a tensor 1025. The tensor 1025 is passed to a PRELU layer 1026. The PRELU layer 1026 outputs the tensor 1027. Returning to FIG. 11, control in the processor 205 progresses from the step 1150 to a reconstruct first tensors step 1160.

At the step 1160 the multi-scale feature reconstruction (MSFR) module 1030, under execution of the processor 205, produces first tensors, as described in relation to FIG. 10A. The step 1160 receives the tensor 1017 generated by operation of the step 1140. The tensor 1017 is passed to an MSFR module 1030, which generates decoded tensors 1055 and 1033. The MSFR module 1030 uses an upsampling module 1032, a downsampling module 1034, a convolutional layer 1036 and a summation module 1038 in implementing step 1160. The upsampling module 1032 receives the tensor 1017 and performs an interpolation to produce the tensor 1033. The tensor 1033 has twice the width and height of tensor 1017. The tensor 1033 is output as P′4 and passed to the downsample module 1034. The downsample module 1034 downsamples the tensor 1033 to produce a tensor 1035 having the same dimensionality as the tensor 1017. The tensor 1035 is provided to a convolution layer 1036 which outputs a tensor 1037. The summation module 1038 adds the tensors 1037 and 1017 to produce the tensor 1055. The tensor 1055 is output as P′5. The tensor P′5 is the smallest tensor in the set of tensors P′4 and P′5, generated using, for example by adding, the first unit of information (1011) with the other tensor 1033 produced by operation of convolution at block 1036. Referring back to FIG. 11, control in the processor 205 progresses from the step 1160 to a reconstruct second tensors step 1170.

At the step 1170 the MSFR module 1030, under execution of the processor 205, produces the second tensors from the tensor 1027. The MSFR module 1030 which generates decoded tensors 1053 and 1043 uses an upsampling module 1042, a downsampling module 1044, a convolutional layer 1046 and a summation module 1048 in implementing step 1170. The tensor 1027 is passed to upsampling module 1042. The upsampling module 1042 performs an interpolation to produce tensor 1043 having twice the width and height of tensor 1027. The tensor 1043 is output as P′2 and passed to a downsample module 1044. The downsample module 1044 downsamples the tensor 1043 to produce a tensor 1045 having the same dimensionality as the tensor 1027. The tensor 1045 is provided to the convolution layer 1046 which outputs a tensor 1047. the summation module 1048 adds the tensors 1047 and 1027 to produce the tensor 1053, which is output as P′3. The tensor P′3 is the smallest tensor in the set of tensors P′2 and P′3, generated using, for example by adding, the first unit of information (1021) with the other tensor 1053 produced by operation of convolution at block 1046. The tensors 1043 1053 1033 1055, i.e., the decoded tensors P′2-P′5 corresponding to tensors P2-P5, form the tensors 149. Referring to FIG. 11, control in the processor 205 progresses from the step 1170 to a perform neural network second portion step 1180. As shown in FIG. 10A, respective tensors of each set plurality of tensors (1055, 1033) and (1053, 1043) has a resolution forming an exponential sequence with a doubling in width and height between successive tensors. For example, width and height of 1033 is double width and height of 1055. The largest tensor in each set of tensors (1033 and 1043) are determined based on an upsampling operation (1032 or 1042 respectively) applied to the feature maps of the unit of information.

At the step 1180 the CNN head 150, under execution of the processor 205, takes the tensors 149 as input on which to perform the remainder of the neural network implemented by the system 100. The method 1100 terminates on implementing the step 1180, having processed tensors associated with one frame of video data. The method 1100 is re-invoked for each frame of video data encoded in the bitstream 143.

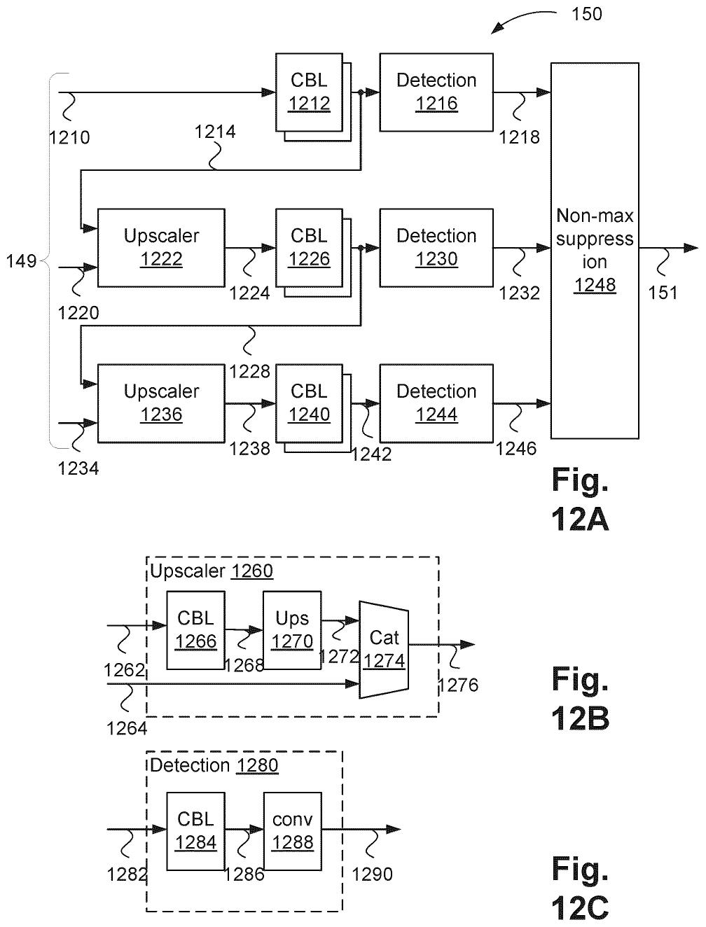

FIG. 12A is a schematic block diagrams showing a head portion 150 of a CNN for object detection. Depending on the task to be performed in the destination device 140, different networks may be substituted for the CNN head 150. Incoming tensors 149 are separated into the tensor of each layer (i.e., tensors 1210, 1220, and 1234). The tensor 1210 is passed to a CBL module 1212 to produce tensor 1214 The tensor 1214 is passed to a detection module 1216 and an upscaler module 1222. The detection module 1216 operated to detect bounding boxes 1218. The bounding boxes 1218 are in the form of a detection tensor. The bounding boxes 1218 are passed to a non-maximum suppression (NMS) module 1248. The NMS module 1248 selects one of multiple inputs generated by detection modules to produce a detection result 151. To produce bounding boxes addressing co-ordinates in the original video data 113, prior to resizing for the backbone portion of the network 114, scaling by the original video width and height is performed. The upscaler module 1222 produces an upscaled tensor 1224 scaled by original video width and height. The upscaled tensor 12224 is passed to a CBL module 1226 The CBL module 1226 produces tensor 1228 as output. The tensor 1228 is passed to a detection module 1230 and an upscaler module 1236. The detection module 1230 operates in a similar manner to the detection module 1216 and produces a detection tensor 1232. The detection tensor 1232 is supplied to the NMS module 1248.

The upscaler module 1236 operates in the same manner as the module 1260 and outputs an upscaled tensor 1238. The upscaled tensor 1238 is passed to a CBL module 1240. The CBL module 1240 operates in the same manner as the modules 1212 and 1226 to output a tensor 1242 to a detection module 1244. The detection module 1244 operates in a similar manner to the detection module 1216 and produces a detection tensor 1246. The detection tensor 1246 is supplied to the NMS module 1248.

The CBL modules 1212, 1226, and 1240 each contain a concatenation of five CBL modules. The upscaler modules 1222 and 1236 are each instances of an upscaler module 1260 as shown in FIG. 12B.

The upscaler module 1260 accepts a tensor 1262 and a tensor 1264 as inputs. The tensor 1262 is passed to a CBL module 1266 to produce a tensor 1268. The tensor 1268 is passed to an upsampler 1270 to produce an upsampled tensor 1272, using nearest-neighbour interpolation or other various methods. A concatenation module 1274 produces a tensor 1276 by concatenating the upsampled tensor 1272 with the input tensor 1264.

The detection modules 1216, 1230, and 1244 are instances of a detection module 1280 as shown in FIG. 12C. The detection module 1260 receives a tensor 1282, which is passed to a CBL module 1284 to produce a tensor 1286. The tensor 1286 is passed to a convolution module 1288, which implements a detection kernel. A detection kernel a 1×1 kernel applied to produce the output on feature maps at the three layers. The detection kernel is 1×1×(B×(5+C)), where B is the number of bounding boxes a particular cell can predict, typically three (3), and C is the number of classes, which may be eighty (80), resulting in a kernel size of two-hundred and fifty five (255) detection attributes. The module 1288 outputs tensor 1290. The constant “5” represents four boundary box attributes (box centre x, y and size scale x, y) and one object confidence level (“objectness”). The result of a detection kernel has the same spatial dimensions as the input feature map, but the depth of the output corresponds to the detection attributes. The detection kernel is applied at each layer, typically three layers, resulting in a large number of candidate bounding boxes. A process of non-maximum suppression is applied by the NMS module 1048 to the resulting bounding boxes to discard redundant boxes, such as overlapping predictions at similar scale, resulting in a final set of bounding boxes as output for object detection.

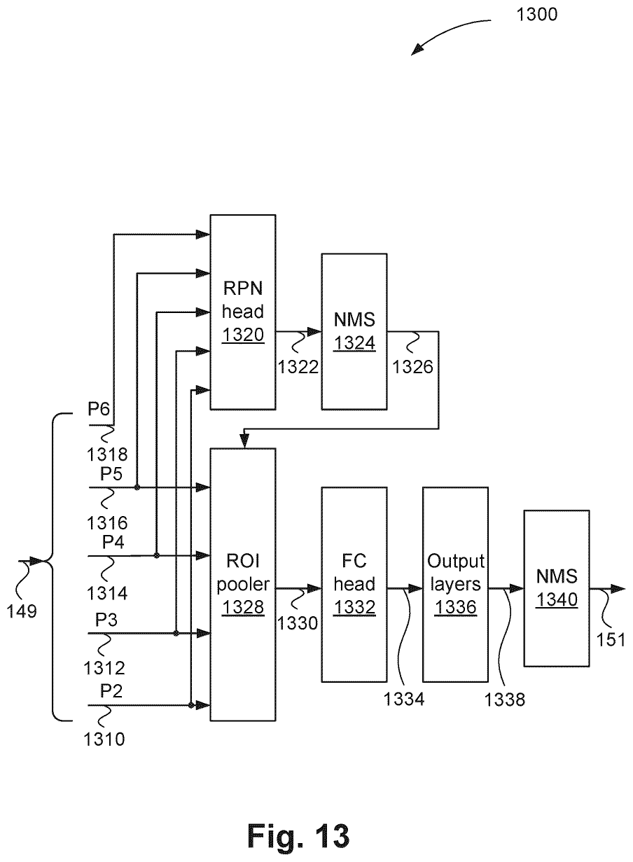

FIG. 13 is a schematic block diagram showing an alternative head portion 1300 of a CNN. The head portion 1300 forms part of an overall network known as ‘Faster RCNN’ and includes a feature network (i.e., backbone portion 400), a region proposal network, and a detection network. Input to the head portion 1300 are the tensors 149. The tensors 149 include P2-P6 layer tensors 1310, 1312, 1314, 1316, and 1318. The P2-P6 tensors 1310, 1312, 1314, 1316, and 1318 are input to a region proposal network (RPN) head module 1320. The RPN head module 1320 performs a convolution on the input tensors, producing an intermediate tensor. The intermediate tensor is fed into two subsequent sibling layers in the module 1320, one for classifications and one for bounding box, or ‘region of interest’ (ROI), regression, as classification and bounding boxes 1322. The classification and bounding boxes 1322 are passed to an NMS module 1324. The NMS module prunes out redundant bounding boxes by removing overlapping boxes with a lower score to produce pruned bounding boxes 1326. The bounding boxes 1326 are passed to a region of interest (ROI) pooler 1328. The ROI pooler 1328 also receives the tensors P2 to P6 and produces fixed-size feature maps from various input size maps using max pooling operations. In the operations performed by 1328 a subsampling takes the maximum value in each group of input values to produce one output value in the output tensor.

In an arrangement of the CNN backbone 400 and the CNN head 1300, the ‘P6’ layer tensor 429 is omitted from the output tensors 115 and in the CNN head 1300, the P6 input tensor 1318 is produced by performing a ‘Maxpool’ operation with stride equal to two on the P5 tensor 1316. Since the P6 layer can be reconstructed from the P5 layer, there is no need to separately encode and decode the P6 layer as an explicit FPN layeramong the first set of tensors or the second set of tensors.

Input to the ROI pooler 1328 are the P2-P5 feature maps 1310, 1312, 1314, and 1316 (corresponding to 1043, 1053, 1033 and 1055 of FIG. 10A, respectively), and region of interest proposals 1326. Each proposal (ROI) from 1326 is associated with a portion of the feature maps (1310-1316) to produce a fixed-size map. The fixed-size map is of a size independent of the underlying portion of the feature map 1310-1316. One of the feature maps 1310-1316 is selected such that the resulting cropped map has sufficient detail, for example, according to the following rule: floor (4+log 2 (sqrt(box_area)/224)), where 224 is the canonical box size. The ROI pooler 1328 thus crops incoming feature maps according to the proposals 1326 producing a tensor 1330. The tensor 1330 is fed into a fully connected (FC) neural network head 1332. The FC head 1332 performs two fully connected layers to produce class score and bounding box predictor delta tensor 1334. The class score is generally an 80-element tensor, each element corresponding to a prediction score for the corresponding object category. The bounding box prediction deltas tensor is an 80×4=320 element tensor, containing bounding boxes for the corresponding object categories. Final processing is performed by an output layers module 1336, receiving the tensor 1334 and performing a filtering operation to produce a filtered tensor 1338. Low-scoring (low classification) objects are removed from further consideration. A non-maximum suppression module 1340 receives the filtered tenor 1334 and removes overlapping bounding boxes by removing the overlapped box with a lower classification score, resulting in an inference output tensor 151.

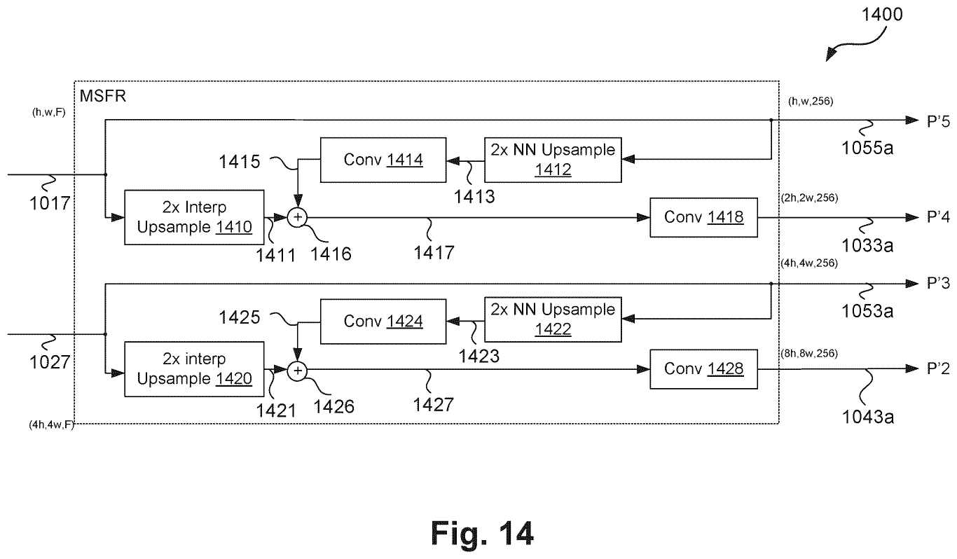

FIG. 14 is a schematic block diagram showing a top-down multi-scale feature reconstruction (MSFR) stage 1400 for the destination device 140. The top-down MSFR stage 1400 is one alternative implementation to the MSFR 1030 of FIG. 10A. Top-down feature reconstruction involves upsampling from lower resolution layers (at the ‘top’ of the FPN) to generate versions of higher resolution layers. Where a plurality of spatial representations of the layers of an FPN are used, the top-down operation is performed to reconstruct each tensor within a given each respective spatial representation. The first combined tensor 1017 and the second combined tensor 1027 are received by the top-down MSFR 1400 and output directly as tensors P′5 1055a and P′3 1053a, respectively. The tensor 1017 is passed to an upsample module 1410. The module 1410 performs a 2× upsampling using interpolation filters to produce a tensor 1411. The tensor 1017 is also passed to an upsample module 1412. The module 1412 performs a nearest-neighbour upsampling to produce a tensor 1413 having twice the width and height of the tensor 1017. The tensor 1413 is passed to convolution layer 1414 to produce tensor 1415, having the same dimensionality as the tensor 1413. A summation module 1416 sums the tensors 1415 and 1411 to produce a tensor 1417. The tensor 1417 is passed to a convolution stage 1418 to produce tensor P′4 1033a. The tensor 1033a has the same dimensionality as the tensor 1417.

The tensor 1027 is passed to an upsample module 1420 which performs a 2× upsampling using interpolation filters to produce a tensor 1421. The tensor 1027 is also passed to an upsample module 1422. The module 1422 performs a nearest-neighbour upsampling to produce a tensor 1423 having twice the width and height of the tensor 1027. The tensor 1423 is passed to convolution layer 1424 to produce tensor 1425, having the same dimensionality as the tensor 1423. A summation module 1426 sums the tensors 1425 and 1421 to produce a tensor 1427. The tensor 1427 is passed to a convolution stage 1428 to produce tensor P′2 1043a, having the same dimensionality as the tensor 1427.

When the top-down MSFR module 1400 is in use, output tensors 1055a, 1033a, 1053a, and 1043a are supplied to the remainder of the network as tensors 1055, 1033, 1053, and 1043, respectively. Although different approaches to reconstructing each FPN layer is possible, in each case the layers of the FPN can be grouped into multiple (e.g., two) sets of layers, each of which is separately fused together in the bottleneck encoder 116 and extracted in the bottleneck decoder 148.

The bottleneck decoder 148, whether implementing an MSFR decoder as the decoder 1030 or the decoder 1400, operates to use the first and second units of information decoded by operation of steps 1110 to 11130 to generate first and second sets of tensors respectively. Each set of tensors can be determined independently, such that the steps 1120 and 1130 can be executed independently, concurrently or in a different order if required. The first set or plurality of tensors is provided by the tensors P′4 and P′5 (1055 and 1033 in FIG. 10A or 1055a and 1033a in FIG. 14). The second set or plurality of tensors is provided by the tensors P′2 and P′3 (1053 and 1043 in FIG. 10A or 1053a and 1043a in FIG. 14). As the first set of tensors relate to P4 and P5, the associate feature maps have a different spatial resolution to the second set relating to P3 and P2). Together, both sets of tensors correspond to a single hierarchical representation of the image frame. For example, the hierarchical representation can be the feature pyramid network produced by operation of the CNN backbone 400 of FIG. 4 or the sets of tensors produced by operation of the CNN backbone 300 of FIG. 3A.

Irrespective of the implementation used for the MSFR decoder, the arrangements described allow each set of the first and second pluralities of tensors to be determined using neural network layers. The layers are typically convolutional, batch normalisation and PReLu layers. Other layers can be used for the SSFC decoders 1010 and 1020, provided decoding from a single packed frame, such as the frame 700, can be achieved.

The first and second sets of tensors can be provided to the CNN head 150 to implement a task such as object detection, frame segmentation or the like. For example, P′5 to P′2 can be processed as shown in relation to FIG. 13.

Alternatively, the CNN 150 of FIG. 12 can be provided with tensors 1210, 1220, and 1234 from the bottleneck decoder 148. In implementations using the CNN head 150 of FIG. 12, the bottleneck decoder 148 operates to output the tensor 1017 from the SSFC decoder 1010, processing the first group The tensor 1017 is convolved with 256 channel input and 1024 channel output to provide tensor 1210 to the CNN head, with the modules 1032, 1034, 1036, and 1038 omitted. FIG. 10B shows a convolutional arrangement 1090 for use with the bottleneck decoder 148 of FIG. 10A when the CNN is implemented in a similar manner to the example of FIG. 12. The arrangement 1090 includes convolutional layers 1060, 1070 and 1080. The tensor 1017 of FIG. 10A is input to the convolutional layer 1060, which outputs the tensor 1210 having 1024 channels. For the second group, tensors 1053 and 1043 are output from the bottleneck decoder 148 with 256 channels each. The tensors 1053 are input to the convolutional layer 1070 which generates the tensor 1220 having 512 channels. The tensors 1043 are input to the convolutional layer 1080 which generates the tensor 1234 having 256 channels. Referring to FIG. 3, the tensor 329 has 1024 channels, which are reduced to 64 channels by the SSFC encoder 550. The tensors 326 and 322 have 512 and 256 channels respectively, which are firstly reduced to 256 channels in the MSFF module 510 and further reduced to 64 channels in the SSFC encoder 530.

In the example implementations described in relation to FIGS. 5 and 10, the first and second tensors (for example 537 and 557) have different dimensions but the same number of channels. In another arrangement of the bottleneck encoder 116 and the bottleneck decoder 148, the number of channels of the second compressed tensor 557, 1011 is different to the number of channels of the first compressed tensor 537, 1021. For example, the second compressed tensor can have a lower or smaller number of channels than the first compressed tensor. Preferably, the second compressed tensor, for the higher spatial resolution FPN layers (P′2 and P′3), has a smaller number of channels than the first compressed tensor, for the lower spatial resolution FPN layers (P′4 and P′5). The number of channels of the second compressed tensor 537 may be 32 or 48 channels. The second compressed tensor 537 has four times the width and height of the first compressed tensor 557 and a reduction in channel count results in a smaller area required for the frame 700. The second compressed tensor 537 represents less decomposed features of the frame 113 and show fewer channels is adequate for achieving high task performance, as a majority of the semantically meaningful information is contained in the first compressed tensor 557.

In an arrangement of the source device 110 and the destination device 140 having a three-layer FPN, for example where a ‘YOLOv3’ network was used, the tensors can be grouped into two sets, a first group having two FPN layers and the second group having one FPN layer. The group having one FPN layer requires bottleneck layers related to the SSFC encoder (530 or 550) and the SSFC decoder (1010 or 1020) but does not require layers related to MSFF 510 or MSFR 1030. Where the channel count differs between layers of the FPN, the concatenation (e.g., 514 or 522) in the MSFF module 510 concatenates such tensors. Additional convolution layers are inserted in the MSFR (e.g., 1030 or 1400) to restore the channel count for each respective FPN layer.

### INDUSTRIAL APPLICABILITY

The arrangements described are applicable to the computer and data processing industries and particularly for the digital signal processing for the encoding and decoding of signals such as video and image signals, achieving high compression efficiency.

The arrangements describe split use of MFSC into two operations, dividing how a hierarchical structure (such as feature pyramid network) of a frame of data is compressed before encoding (and correspondingly decompressed after decoding). In separately applying MFSC techniques, a degree of cross-layer fusion can be achieved without the severe degradation of spatial detail incurred using a single MFSC operation. For tasks requiring preservation of greater spatial detail, such as instance segmentation, the resulting mAP is higher using separate MSFC techniques than if all FPN (hierarchical) layers are merged into a single tensor. Further, different numbers of channels can be used in different instances of MFSC, thereby limiting area increases if required. MFSC is traditionally used to ‘fuse’ or constrict all data in an FPN. In contrast to fusing or constricting all data in a FPN, use of more than one instance of MFSC with a single hierarchical structure or FPN can implement MFSC while limiting unfavourable effects of mAP.

The foregoing describes only some embodiments of the present invention, and modifications and/or changes can be made thereto without departing from the scope and spirit of the invention, the embodiments being illustrative and not restrictive.

In the context of this specification, the word “comprising” means “including principally but not necessarily solely” or “having” or “including”, and not “consisting only of”. Variations of the word “comprising”, such as “comprise” and “comprises” have correspondingly varied meanings.

1. A method of decoding at least a plurality of tensors forming a hierarchical representation of feature maps for a single frame from a bitstream, the method comprising:
decoding a first unit of information from the bitstream;
decoding a second unit of information from the bitstream;
determining a first plurality of tensors from the first unit of information, feature maps of at least one tensor of the first plurality of tensors having a different spatial resolution from feature maps of other tensor(s) of the first plurality of tensors; and
determining a second plurality of tensors from the second unit of information, feature maps of at least one tensor of the second plurality of tensors having a different spatial resolution from feature maps of other tensor(s) of the second plurality of tensors,
wherein feature maps of each tensor of the first plurality of tensors have different spatial resolution from feature maps of each tensor of the second plurality of tensors, and the tensors of the first plurality of tensors and the second plurality of tensors correspond to the hierarchical representation of feature maps for the single frame.

2. The method according to claim 1, wherein respective tensors of the first and second pluralities of tensors have resolutions forming an exponential sequence with a doubling in width and height between successive tensors.

3. The method according to claim 1, wherein the first and second pluralities of tensors have a different number of channels.

4. The method according to claim 1, wherein the plurality of tensors of the first plurality of tensors and the second plurality of tensors with higher spatial resolutions has a smaller number of channels than the other plurality of tensors.

5. The method according to claim 1, wherein largest tensors of each of the first and second plurality of tensors are determined based on an upsampling operation applied to feature maps of the corresponding one of the first and second units of information.

6. The method according to claim 1, wherein determination of the first plurality of tensors and determination of the second plurality of tensors are independent from each other.

7. The method according to claim 1, wherein the first plurality of tensors and the second plurality of tensors are determined using neural network layers.

8. The method according to claim 1, wherein the first unit of information is used to determine the smallest tensor in the first plurality of tensors.

9. The method according to claim 1, wherein the second unit of information is used to determine the smallest tensor in the second plurality of tensors.

10. A method of encoding at least a plurality of tensors to a bitstream, the plurality of tensors forming a hierarchical representation of feature maps for a single frame, the method comprising:
using a convolutional operation to determine a first unit of information from a first plurality of tensors, feature maps of at least one tensor of the first plurality of tensors having a different spatial resolution from feature maps of other tensor(s) of the first plurality of tensors;
using a convolutional operation to determine a second unit of information from a second plurality of tensors, feature maps of at least one tensor of the second plurality of tensors having a different spatial resolution from feature maps of other tensor(s) of the second plurality of tensors, and wherein feature maps of each tensor of the first plurality of tensors have different spatial resolution from feature maps of each tensor of the second plurality of tensors, and the tensors of the first plurality of tensors and the second plurality of tensors correspond to the hierarchical representation of feature maps for the single frame;
encoding the first unit of information to the bitstream; and
encoding the second unit of information to the bitstream.

11. A decoder for decoding at least a plurality of tensors forming a hierarchical representation of feature maps for a single frame from a bitstream, the decoder configured to:
decode a first unit of information from the bitstream;
decode a second unit of information from the bitstream;
determine a first plurality of tensors from the first unit of information, feature maps of at least one tensor of the first plurality of tensors having a different spatial resolution from feature maps of other tensor(s) of the first plurality of tensors; and
determine a second plurality of tensors from the second unit of information, feature maps of at least one tensor of the second plurality of tensors having a different spatial resolution from feature maps of other tensor(s) of the second plurality of tensors,
wherein feature maps of each tensor of the first plurality of tensors have different spatial resolution from feature maps of each tensor of the second plurality of tensors, and the tensors of the first plurality of tensors and the second plurality of tensors correspond to the hierarchical representation of feature maps for the single frame.

12. An encoder for encoding at least a plurality of tensors to a bitstream, the plurality of tensors forming a hierarchical representation of feature maps for a single frame, the encoder configured to:
use a convolutional operation to determine a first unit of information from a first plurality of tensors, feature maps of at least one tensor of the first plurality of tensors having a different spatial resolution from feature maps of other tensor(s) of the first plurality of tensors;
use a convolutional operation to determine a second unit of information from a second plurality of tensors, feature maps of at least one tensor of the second plurality of tensors having a different spatial resolution from feature maps of other tensor(s) of the second plurality of tensors, and wherein feature maps of each tensor of the first plurality of tensors have different spatial resolution from feature maps of each tensor of the second plurality of tensors, and the tensors of the first plurality of tensors and the second plurality of tensors correspond to the hierarchical representation of feature maps for the single frame;
encode the first unit of information to the bitstream; and
encode the second unit of information to the bitstream.

13. A non-transitory computer-readable storage medium which stores a program for executing a method of decoding at least a plurality of tensors forming a hierarchical representation of feature maps for a single frame from a bitstream, the method comprising:
decoding a first unit of information from the bitstream;
decoding a second unit of information from the bitstream;
determining a first plurality of tensors from the first unit of information, feature maps of at least one tensor of the first plurality of tensors having a different spatial resolution from feature maps of other tensor(s) of the first plurality of tensors; and
determining a second plurality of tensors from the second unit of information, feature maps of at least one tensor of the second plurality of tensors having a different spatial resolution from feature maps of other tensor(s) of the second plurality of tensors,
wherein feature maps of each tensor of the first plurality of tensors have different spatial resolution from feature maps of each tensor of the second plurality of tensors, and the tensors of the first plurality of tensors and the second plurality of tensors correspond to the hierarchical representation of feature maps for the single frame.

14. A system comprising:
a memory; and
a processor, wherein the processor is configured to execute code stored on the memory for implementing a method of decoding at least a plurality of tensors forming a hierarchical representation of feature maps for a single frame from a bitstream, the method comprising:
decoding a first unit of information from the bitstream;
decoding a second unit of information from the bitstream;
determining a first plurality of tensors from the first unit of information, feature maps of at least one tensor of the first plurality of tensors having a different spatial resolution from feature maps of other tensor(s) of the first plurality of tensors; and
determining a second plurality of tensors from the second unit of information, feature maps of at least one tensor of the second plurality of tensors having a different spatial resolution from feature maps of other tensor(s) of the second plurality of tensors,
wherein feature maps of each tensor of the first plurality of tensors have different spatial resolution from feature maps of each tensor of the second plurality of tensors, and the tensors of the first plurality of tensors and the second plurality of tensors correspond to the hierarchical representation of feature maps for the single frame.
